(19) United States
(12) Patent Application Publication
(10) Pub. No.: US 2024/0404996 A1
(43) Pub. Date: Dec. 5, 2024

(54) PACKAGE WITH VERTICALLY STACKED DEVICES, AND FABRICATION METHODS THEREOF

(71) Applicant: Qorvo US, Inc., Greensboro, NC (US)

(72) Inventors: Jonathan Hale Hammond, Oak Ridge, NC (US); Robertus Petrus van Kampen, ‘s-Hertogenbosch (NL); Roberto Gaddi, Rosmalen (NL); Paul Castillou, San Jose, CA (US); Lance Barron, Greensboro, NC (US)

(21) Appl. No.: 18/673,165

(22) Filed: May 23, 2024

Related U.S. Application Data
(60) Provisional application No. 63/505,830, filed on Jun. 2, 2023.

(51) Int. Cl. H01L 25/065; H01L 23/00; H01L 23/31; H01L 25/00

(52) U.S. Cl. CPC H01L 25/0657; H01L 23/3107; H01L 24/20; H01L 24/32; H01L 25/50; H01L 2224/21; H01L 2224/32145; H01L 2225/06548

(57) ABSTRACT

A package is provided. The package includes a first semiconductor device having a first functional layer. The first functional layer includes a first functional component. The package also includes a second semiconductor device over the first semiconductor device. The second semiconductor device includes a second functional layer having a second functional component. The second functional layer is over a base layer. The base layer is coupled to the second functional layer on a first surface, and is coupled to the first functional layer on a second surface. The first surface and the second surface are on opposite sides of the base layer.

### RELATED APPLICATIONS

This application claims priority to U.S. Provisional Patent Application No. 63/505,830, filed Jun. 2, 2023, which is incorporated by reference herein in its entirety.

### FIELD OF THE INVENTION

This disclosure relates to microelectronics package and processes for making the microelectronics package. In particular, this disclosure relates to microelectronics package with vertically stacked devices, and fabrication methods for forming the microelectronics package.

### BACKGROUND

The wide utilization of cellular and wireless devices drives the rapid development of radio frequency (RF) technologies. Stacked-device assembly technology currently attracts substantial attention in portable RF applications, due to the popularity of portable consumer electronic products, such as smart phones, tablet computers, and so forth. Stacked-device assemblies are designed to achieve electronics densification in a small footprint. For example, a microelectronics package can include a MEMS device (e.g., a MEMS chip configured to generate an RF signal) bonded to a controller chip such that the controller chip can control the transmission of the RF signal. The microelectronics package can then be electrically coupled to an external circuit that utilize the RF signal and/or control signal for various applications.

However, the RF signal transmission in such package can be interfered by other signals and can suffer from non-linearity. The fabrication process to bond the MEMS device and the controller often requires high-precision aligning, increasing the cost of the product. Thus, there is a need to make microelectronics packages of lower cost, simpler fabrication process, and having RF signals of higher linearity.

### SUMMARY

An aspect of the present disclosure provides a package. The package includes a first semiconductor device having a first functional layer that has a first functional component. The package also includes a second semiconductor device over the first semiconductor device. The second semiconductor device includes a second functional layer having a second functional component. The second functional layer is over a base layer. The base layer is coupled to the second functional layer on a first surface, and is coupled to the first functional layer on a second surface. The first surface and the second surface are on opposite sides of the base layer.

In some embodiments, the package further includes an adhesive layer between the first semiconductor device and the second semiconductor device. A first surface of the adhesive layer is in contact with the base layer, and a second surface of the adhesive layer is in contact with the first functional layer. The first surface and the second surface of the adhesive layer are on opposite sides of the adhesive layer.

In some embodiments, the package further includes a molding layer over the first functional layer, and encapsulating the second semiconductor device and the adhesive layer. The second functional layer is in contact with the molding layer on a first surface and in contact with the base layer on a second surface. The first surface and the second surface of the second functional layer are on opposite sides of the second functional layer.

In some embodiments, the package further includes a routing layer over the molding layer, the routing layer having a conductive routing component encapsulated in an insulating layer. The package may also include a first conductive via aside from the second semiconductor device and extending in the molding layer, and a second conductive via over the second functional layer and extending in the molding layer.

In some embodiments, the first conductive via is conductively coupled to the conductive routing component and the first functional layer, the second conductive via is conductively coupled to the conductive routing component and the second functional layer, and the second functional component is conductively connected to the first functional component through the first conductive via, the second conductive via, and the conductive routing component.

In some embodiments, the package further includes another second conductive via over the second functional layer and extending in the molding layer, the other second conductive via located away from the second conductive layer by a pitch distance. A ratio between the pitch distance and a vertical dimension of the second conductive via is about 2:1.

In some embodiments, the base layer includes at least one of a silicon base layer or a molding base layer.

In some embodiments, the first semiconductor device includes another base layer, the first functional layer being over the other base layer. The other base layer includes at least one of a silicon base layer or a molding base layer.

In some embodiments, the first semiconductor device includes another base layer, the first functional layer being over the other base layer. The base layer and the other base layer may each include a molding base layer.

In some embodiments, the first functional component includes a controller component and the second functional component includes a MEMS component, the first functional component includes a bulk acoustic wave (BAW) component and the second functional component includes a low noise amplifier (LNA) component, the first functional component includes a power amplifier component and the second functional component includes a power management chip component, or the first functional component includes a MEMS component and the second functional component includes a controller component.

Another aspect of the present disclosure provides a method for forming a package. The method includes forming a first structure comprising an adhesive layer and a first functional layer having a first functional component, the first functional layer being over a base layer, forming a second structure comprising a second functional layer having a second functional component, and attaching the first structure to the second structure through the adhesive layer such that the first functional layer and the second functional layer are on opposite sides of the base layer.

In some embodiments, the forming of the second structure includes forming a first conductive via structure in contact with the second functional layer.

In some embodiments, the forming of the first structure includes forming the adhesive layer on the base layer, the adhesive layer and the first functional layer being on opposite sides of the base layer. The forming of the first structure may also include forming a second conductive via structure in contact with the first functional layer.

In some embodiments, the method further includes forming a molding material layer over the second structure, the molding material layer encapsulating the first structure and the first conductive via structure. The method may also include planarizing the molding material layer, the first conductive via structure, and the second conductive via structure to form a molding layer, a first conductive via, and a second conductive via. The molding layer, the first conductive via, and the second conductive via are coplanar with one another on a respective surface away from the second functional layer.

In some embodiments, the method of further includes forming a routing layer over the molding layer, the first conductive via, and the second conductive via, the routing layer comprising a conductive routing component conductively coupled to the first conductive via and the second conductive via. The method may also include forming a soldering feature conductively coupled to at least one of the first conductive via, the second conductive via, or the conductive routing component.

In some embodiments, the base layer includes a non-molding material. The forming of the first structure includes replacing the base layer with a molding base layer, and forming the adhesive layer disposed on the molding base layer, the adhesive layer and the first functional layer being on opposite sides of the molding base layer. The forming of the first structure may also include forming a second conductive via structure in contact with the first functional layer, and forming a first molding material layer over the first functional layer, the first molding material layer encapsulating the second conductive via structure.

In some embodiments, the forming of the first structure includes, before the replacing of the base layer with the molding base layer: forming a plurality of second conductive via structures on a first device material layer, the first device material layer being disposed on a first surface of a base material layer; forming a layer of mold material over the first device material layer such that the layer of mold material encapsulates the plurality of second conductive via structures; thinning a second surface of the base material layer, the first and second surfaces of the base material layer being on opposite sides of the base material layer; and dicing the layer of mold material and the thinned base material layer to form the first structure.

In some embodiments, the method further includes: forming a second molding material layer over the second functional layer, the second molding material layer encapsulating the first structure and the first conductive via structure; and planarizing the first and second molding material layers, the first conductive via structure, and the second conductive via structure to form a molding layer, a first conductive via, and a second conductive via. The molding layer, the first conductive via, and the second conductive via are coplanar with one another on a respective surface away from the second functional layer.

In some embodiments, the method further includes: forming a routing layer over the molding layer, the first conductive via, and the second conductive via, the routing layer comprising a conductive routing component conductively coupled to the first conductive via and or second conductive via; and forming a soldering feature conductively coupled to at least one of the first conductive via, the second conductive via, or the conductive routing component.

In some embodiments, forming the controller structure includes: forming the second functional layer over a non-molding base layer; and replacing the non-molding base layer with a second molding base layer

### BRIEF DESCRIPTION OF THE DRAWINGS

FIGS. 1A-1C each illustrates an exemplary package according to embodiments of the present disclosure.

FIG. 2 illustrates a flowchart of an exemplary fabrication process for forming a package according to embodiments of the present disclosure.

FIGS. 3A-3M illustrate cross-sectional views of a package at various stages of an exemplary fabrication process according to embodiments of the present disclosure.

FIGS. 4A-4K illustrate cross-sectional views of a package at various stages of another exemplary fabrication process according to embodiments of the present disclosure.

FIGS. 5A-5D illustrate cross-sectional views of a package at various stages of another exemplary fabrication process according to embodiments of the present disclosure.

FIGS. 6A and 6B illustrate cross-sectional views of a package at various stages of another exemplary fabrication process according to embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

Spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Reference will now be made in greater detail to various embodiments of the subject matter of the present disclosure, some embodiments of which are illustrated in the accompanying drawings.

The disclosure is intended for the mobile communications space in multi-chip modules involving mixed (heterogenous) technologies. These technologies are fabricated at a variety of wafer diameters whereas many final assembly lines operate at the 300 mm diameter or above. Embodiments of the present disclosure can be fabricated on any wafer size.

As the power, number of functions, and efficiency increase in mobile communications devices, the area (XYZ) occupied by the components providing these functions continues to decrease. Stacking die vertically in multi-die modules significantly reduces XY area. In stacked die packages, close proximity of active devices, particularly if they are face to face, can lead to unwanted coupling of or distortion of their outputs. Also, high power signals in such packages can overheat the devices if the thermal egress is improperly managed. It is challenging to realize electrical connections between two chips that do not face each other. Thinning the smaller chips with interconnect pillars sufficient to keep a low overall package profile can lead to breakage. Handling small chips with interconnect pillars on them can limit the size dimensions of those chips. Also, silicon substrates are known sources of distortion in large signal RF devices. In addition, flip-chip die to wafer attachment processes can take a long time and subject the final product to unwanted thermal treatment. The high temperature steps of a stacked die assembly process can diminish final product performance or reliability.

Microelectronics package, having a MEMS chip vertically stacked with a controller chip particularly, often suffers from non-linearity caused by various reasons as mentioned above. In the microelectronics package, the MEMS chip is often bonded to the controller chip in a face-to-face manner (e.g., flip-chip bonding) such that the distance between the MEMS component (e.g., disposed in a MEMS device layer) and the controlling device (e.g., disposed in a controlling device layer) is minimized. The electrical connection between the MEMS device layer and the controlling device layer often includes a conductive material such as metal, e.g., soldering features. RF signal generated by the MEMS device is then transmitted to the controlling device through these soldering features. The microelectronics package is further conductively coupled to an external circuit using conductive vias and/or soldering features. The RF signal can then be further transmitted to the external circuit through the conductive vias and soldering features from the controller chip. Because the external circuit is often positioned over the back side of the MEMS chip (e.g., over the side away from the MEMS device layer), the conductive vias thus extend from the controlling device layer to the external circuit (e.g., or the soldering features that are in contact with the external circuit) for signal transmission. As a result, the RF signal is required to travel from the MEMS chip to the controller chip, and from the controller chip to the external circuit. The undesirably long transmission route of the RF signal can increase the non-linearity of the RF signal due to the surrounding structures/devices. For example, the RF signal is more susceptible to interference from neighboring structures/devices such as the base layer of the MEMS chip, which is typically made of silicon. In some cases, silicon can adversely impact the linearity of the RF signal, e.g., under high frequency and/or in a more compact packaging. In addition, the fabrication of such microelectronics package often demands high-precision alignment, e.g., of the soldering features between the MEMS chip and the controller chip, potentially increasing the cost of the microelectronics package.

Embodiments of the present disclosure provide a package (e.g., a microelectronics package) configured to reduce the non-linearity of the RF signal generated by the bonded device at a lower cost. Different from an existing package, the RF device (e.g., a device that generates an RF signal such as a MEMS chip/chip, a bulk acoustic wave (BAW) and/or surface acoustic wave (SAW) die/device, or a power amplifier (PA)) in the package of the present disclosure is attached to a another device (e.g., a controller chip, a low noise amplifier (LNA), or a power management chip/dic) in a “face-up” configuration such that the functional layer of the RF device (e.g., having the functional RF component) of the RF device and the functional layer of the other device face the same direction, e.g., an external circuit, which can be an evaluation board (EVB) bonded over/above the package (or above the RF device). The RF signal generated by the RF device layer can be transmitted to the external circuit directly, e.g., without having to travel to the other device first before being transmitted to the external device by the other device. Compared to an existing microelectronics package, the RF signal in the disclosed package has a shorter transmission route, and is less susceptible to interference from the surroundings. To facilitate the transmission of the RF signal and another signal (e.g., a control signal or another RF signal) from the other device, the disclosed package includes a routing layer that can jointly or separately transmit the RF signal and the other signal from the other device. Compared to an existing package that typically uses soldering features for bonding two devices, the two devices of the present disclosure are coupled together using an adhesive layer, such as epoxy, glue, and/or tape, reducing the complexity and cost of the fabrication. In some embodiments, the material (e.g., the base layer of the RF device, often including silicon) between the functional layers of the two devices is replaced with a material that yields low RF coupling, such as a molding compound. In some embodiments, the material of the base layer of the other device is also replaced with a material with low RF coupling, such as a molding compound. By reducing the use of silicon (e.g., typically known to cause RF distortion), the interference to the RF signal can be further reduced.

The methods and structures of this disclosure can be employed to form packages of various different combinations of devices. In an embodiment, a microelectromechanical system (MEMS) die/chip (e.g., a smaller device) is bonded onto a controller die (e.g., a larger device). In another embodiment, a BAW/SAW die (e.g., a smaller device) is bonded onto a low noise amplifier die (e.g., a larger device). In another embodiment, a power amplifier (PA) die (e.g., a smaller device) is bonded onto a power management chip (e.g., a larger device). In some embodiments, a controller die (e.g., a smaller device) is bonded onto a MEMS die (e.g., a larger device).

In some embodiments, one of the component technologies in the package is fabricated on a 300 mm wafer. This permits the solution to be compatible with the predominant diameter of available assembly lines worldwide currently. In the present disclosure, two or more technologies/wafers are thinned and stacked vertically to reduce XY area while maintaining a low profile height. In doing so, the proximity of the components increases. By arranging the chips to have the active circuit side of each facing the same direction (e.g., a customer evaluation board or EVB), a helpful separation between them is maintained, limiting electrical and thermal coupling.

In the disclosure, placing the highest power RF device in the module closest to and facing the customer EVB permits thermal energy to be carried out of the device and into the EVB. Forming interconnect pillars on the front face of the smaller chip, molding that face and then grinding to reveal the interconnect pillars can make it easier or faster to handle that chip in the assembly flow, and for the smaller chip to be subsequently thinned before placing in the module. All of this can be completed in wafer form. Also, forming all interconnect pillars on all die tall enough that they can be revealed via thinning after placement of the smaller die and the final molding step followed by forming redistribution metal layers between them is a simple and low cost way to realize connections with both/all chips in the module at all levels of the module.

In some embodiments, the silicon substrates (if they exist in the component chips/wafers) can be ground or etched away and replaced with final assembly mold compound in one, several, or all module dies. This mold compound can be one which is more thermally conductive than the common or typical compound used. Mold compound instead of silicon in the package will reduce or eliminate signal distortion from those substrates known to occur in RF large signal applications. By using a die attach material instead of a flip chip/reflow to mount the smaller die to the larger companion die, the thermal budget of the overall assembly flow is reduced and the speed with which the assembly can occur increased and/or associated time for assembly reduced.

In some embodiments, both/all chips in a multi-chip stacked die module face the customer EVB. In some embodiments, one/several/all silicon substrates if present area replaced by mold compound. The smaller chip or chips attached to the larger wafer can have their own interconnect pillars formed on them which are then ground to be revealed along with the interconnect pillars of the larger carrier chip. In some embodiments, both chips are then connected by one or more conductive/metal redistribution layers. The smaller chip(s) may be attached to the larger carrier wafer by adhesive, not flip chip on soldering features/balls and reflow. In some embodiments, the smaller chips with interconnect pillars formed can have front faces molded and ground to reveal the pillars to make the smaller chips easier to handle. These chips can also be thinned as needed to limit overall solution height. In some embodiments, the stacked MEMS/RF device could be an RF MEMS switch, and the larger carrier wafer could be a complementary metal-oxide semiconductor (CMOS) controller of the RF MEMS switch. The stacked MEMS/RF device could also be a power amplifier or bulk acoustic wave device, and the larger carrier could provide power management.

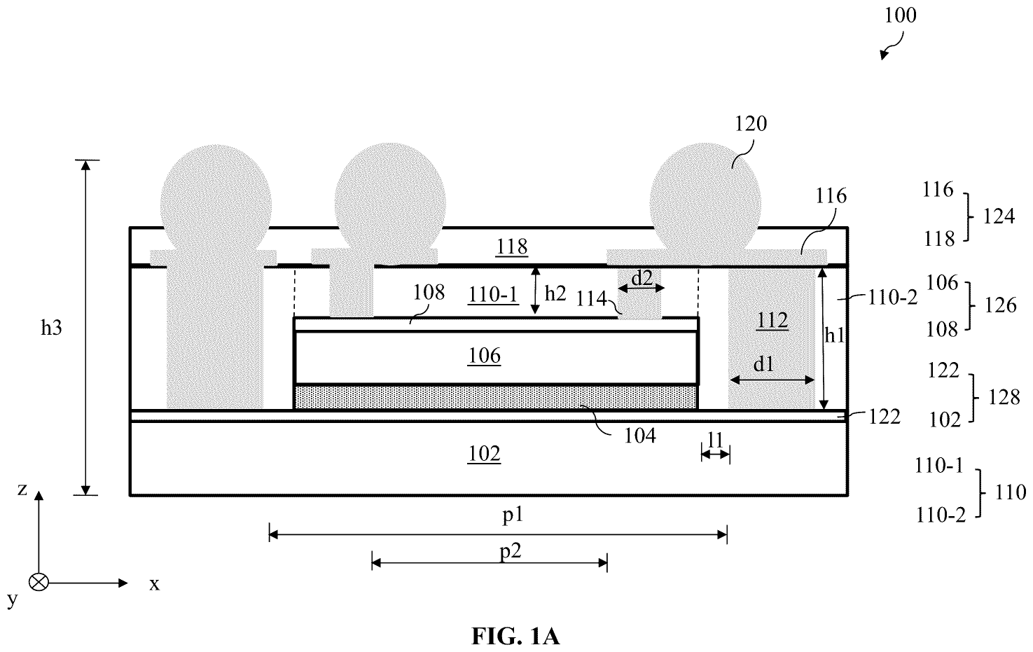

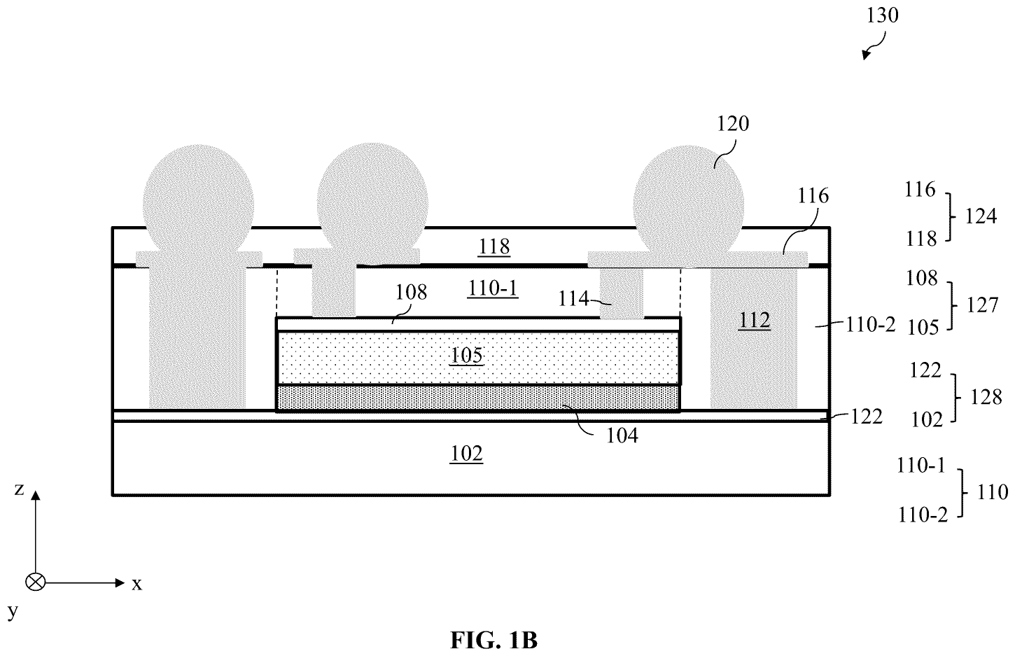

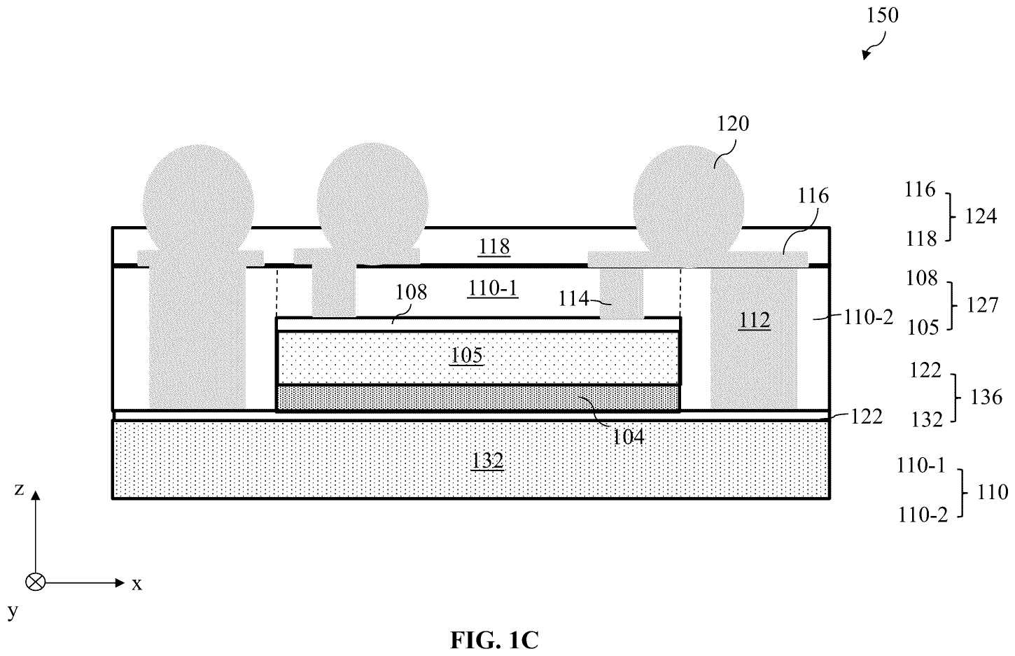

FIGS. 1A-1C illustrate different packages each having a “face-up” configuration. A package (e.g., a microelectronics package) is formed by attaching a first semiconductor device (e.g., a smaller device) and a second semiconductor device (e.g., a larger device). The first semiconductor device includes a first functional layer that includes a first functional component, and the second semiconductor device includes a second functional layer that includes a second functional component. The first functional layer and the second functional layer may face the same direction. In some embodiments, an RF signal can be generated by the first semiconductor device, and another signal (e.g., a control signal) may be generated by the second semiconductor device. The RF signal and the other signal are transmitted through a routing layer and a plurality of soldering features to an external circuit. For case of illustration, in FIGS. 1A-1C, the first semiconductor device is described as a MEMS device, and the second device is described as a controller device. In other various embodiments, any suitable combinations of devices (e.g., a smaller device transmitting an RF signal, and a larger device transmitting another other signal) also fall in the scope of this disclosure. For example, the first semiconductor device can include a BAW/SAW die and a second semiconductor device can include a low noise amplifier die. In another example, the first semiconductor device can include a power amplifier (PA) die and the second semiconductor device can include a power management chip. In a further example, the first semiconductor device can include a controller die and the second semiconductor device can include a MEMS die.

FIG. 1A illustrates a package 100 having bonded devices with a “face-up” configuration, according to some embodiments. Package 100 may include a MEMS device 126 (e.g., a first semiconductor device) vertically stacked with a controller device 128 (e.g., a second semiconductor device). MEMS device 126 may also be referred to as a MEMS chip or a MEMS die. Package 100 may include an adhesive layer 104 connecting the lower surface (e.g., back side) of MEMS device 126 with the upper surface (e.g., front side) of controller device 128. Package 100 may also include a molding layer 110 encapsulating MEMS device 126, a routing layer 124 over molding layer 110, one or more first conductive vias 112 extending between routing layer 124 and controller device 128, and one or more second conductive vias 114 extending between routing layer 124 and MEMS device 126. A first conductive via 112 and a second conductive via 114 can be conductively coupled by a conductive routing component 116 in routing layer 124. Package 100 may further include one or more soldering features 120 conductively connected to routing layer 124. Package 100 can be conductively coupled to an external circuit (not shown) through soldering features 120.

Controller device 128 may include a base layer 102 and a controlling device layer 122 (e.g., a functional layer) disposed over base layer 102. Controlling device layer 122 may include a controller component (e.g., a functional component) that generates a control signal for the controlling of MEMS device 126. In some embodiments, controller device 128 includes a CMOS wafer. Controlling device layer 122 may be formed by one or more back-end-of-line (BEOL) structures/devices, one or more middle-end-of-line (MEOL) structures/devices, and one or more front-end-of-line (FEOL) structures/devices. In some embodiment, the BEOL, MEOL, and/or FEOL structures/devices may form one or more transistors such as a switch field-effect transistor (FET) that control MEMS device 126. For example, the BEOL, MEOL, and/or FEOL structures/devices may include an active layer that includes a source electrode, a drain electrode, and a channel between the source electrode and the drain electrode. In some embodiments, the BEOL, MEOL, and/or FEOL structures/devices may include a plurality of metallization layers embedded in a plurality of intermetal dielectrics. The metallization layers may be conductively connected to the transistors and may route the control signal to a conductive via (e.g., first conductive via 112) that transmits the control signal to an external circuit. In various embodiments, controlling device layer 122 may include one or more suitable conductive materials (e.g., copper (Cu), tungsten (W), aluminum copper (AlCu), molybdenum (Mo), titanium nitride (TiN), and/or platinum (Pt)), one or more semiconductor materials (e.g., silicon (Si), germanium (Ge), silicon carbide (SiC), and/or gallium arsenide (GaAs)), and/or one or more insulating materials (e.g., silicon oxide, silicon nitride, silicon oxynitride, Phosphosilicate Glass (PSG), Boroilicate Glass (BSG), Boron-Doped Phosphosilicate Glass (BPSG), Fluorine-Doped Silicate Glass (FSG), Tetraethyl orthosilicate (TEOS), and/or carbon). In some embodiments, controlling device layer 122 includes a redistribution layer over the controller component and electrically connected to first conductive vias 112. The redistribution layer may route the signals generated by the controller component (e.g., control signal) to a desired location where first conductive vias 112 are formed. The redistribution layer may make the routing/signal transmission easier. In some embodiments, the redistribution layer may be a single-layer structure or a multi-layer structure that includes a suitable dielectric material such as silicon oxide, silicon nitride, and/or silicon oxynitride, or other suitable insulating materials such as glass, resin, etc. The redistribution layer may also include one or more metal layers embedded in the dielectric/insulating material, the metal layers include a suitable conductive material such as copper (Cu), tungsten (W), aluminum copper (AlCu), molybdenum (Mo), titanium nitride (TiN), gold (Au), and/or platinum (Pt)).

Base layer 102 may be positioned at the lower surface (e.g., lower surface) of controlling device layer 122, e.g., an upper surface (e.g., upper surface) of base layer 102 may be coupled to the lower surface of controlling device layer 122. Base layer 102 may provide support to controlling device layer 122 and may have desirably high stiffness and thermal conductivity, and low interference to controlling device layer 122. In some embodiments, base layer 102 includes a silicon substrate and/or a glass substrate.

MEMS device 126 may be coupled to the upper surface of controller device 128. MEMS device 126 may include a MEMS device layer 108 (e.g., a functional layer) and a base layer 106. A total thickness of MEMS device 126 may be between about 5 μm and about 100 μm, such as 50 μm. As shown in FIG. 1A, an upper surface of base layer 106 may be coupled to a lower surface of MEMS device layer 108, and a lower surface of base layer 106 may be coupled to the upper surface of controller device 128 (or controlling device layer 122) through adhesive layer 104. MEMS device layer 108 may include a MEMS component (e.g., a functional component) that generates an RF signal. In various embodiments, the MEMS component can include any suitable devices/structures such as switches, sensors, and the like. MEMS device layer 108 may also include other structures for the proper operations of the MEMS component. For example, MEMS device layer 108 may include a MEMS cavity in which the MEMS component is positioned. The MEMS component can actuate in the MEMS cavity and interact with the RF signal. MEMS device layer 108 may also include transistors, intermetal dielectric layers, metallization layers, conductive vias, or the like to process, transmit, and/or receive signals. In various embodiments, MEMS device layer 108 includes one or more suitable conductive materials (e.g., copper (Cu), tungsten (W), aluminum copper (AlCu), molybdenum (Mo), titanium nitride (TiN), gold (Au), and/or platinum (Pt)), one or more semiconductor materials (e.g., silicon (Si), germanium (Ge), silicon carbide (SiC), and/or gallium arsenide (GaAs)), one or more insulating materials (e.g., silicon oxide, silicon nitride, silicon oxynitride, Phosphosilicate Glass (PSG), Boroilicate Glass (BSG), Boron-Doped Phosphosilicate Glass (BPSG), Fluorine-Doped Silicate Glass (FSG), Tetraethyl orthosilicate (TEOS), and/or carbon), and/or one or more piezoelectric materials (e.g., aluminum nitride (AlN), zinc oxide (ZnO), and/or aluminum scandium nitride (AlScN)).

In some embodiments, MEMS device layer 108 includes a redistribution layer over the controller component and electrically connected to second conductive vias 114. The redistribution layer may route the signals generated by the controller component (e.g., control signal) to a desired location where second conductive vias 114 are formed. The redistribution layer may make the routing/signal transmission easier. In some embodiments, the redistribution layer may be a single-layer structure or a multi-layer structure that includes a suitable dielectric material such as silicon oxide, silicon nitride, and/or silicon oxynitride, or other suitable insulating materials such as glass, resin, etc. The redistribution layer may also include one or more metal layers embedded in the dielectric/insulating material, the metal layers include a suitable conductive material such as copper (Cu), tungsten (W), aluminum copper (AlCu), molybdenum (Mo), titanium nitride (TIN), gold (Au), and/or platinum (Pt)).

Base layer 106 may provide support to MEMS device layer 108 and may have desirably high stiffness and thermal conductivity. Base layer 106 may have little or no electrical conductivity. In some embodiments, base layer 106 can also include silicon, glass, silicon dioxide, silicon nitride, carbon, etc. For example, base layer 106 may include a thinned silicon substrate and/or a thinned glass substrate.

Adhesive layer 104 may be positioned between the lower surface of base layer 106 and the upper surface of controlling device layer 122 (e.g., controller device 128). Adhesive layer 104 may have desirably high thermal conductivity and little or no electrical conductivity. Adhesive layer 104 may include any suitable adhesive material such as glue, epoxy, polymer, tape, etc. In some embodiments, little or no electrical connection is formed between MEMS device 126 and controller device 128 through adhesive layer 104. In some embodiments, adhesive layer 104 may fully cover the lower surface of base layer 106 (or MEMS device 126) such that no molding compound is disposed between the lower surface of MEMS device 126 and the upper surface of controller device 128 (or controlling device layer 122).

Molding layer 110 may be disposed on the upper surface of controlling device layer 122, and may encapsulate adhesive layer 104 and MEMS device 126 over controller device 128. Mold layer 110 may cover (e.g., be in contact with) the side surfaces of adhesive layer 104 and MEMS device 126, and may cover (e.g., be in contact with) the upper surface of MEMS device layer 108. Molding layer 110 may have little or no electrical conductivity and desirably high thermal conductivity and stiffness. In some embodiments, molding layer has a desirably low RF coupling and thus has little or no interference with the RF signal and/or the control signal. Molding layer 110 may include a molding compound such as molding epoxy, a nitride such as silicon nitride, an oxide such as silicon oxide, phosphosilicate glass (PSG), borosilicate glass (BSG), boron-doped phosphosilicate glass (BPSG), phenolic hardener, silica, pigment, and/or a combination thereof. Molding layer 110 may also include thermoplastics or thermoset polymer materials, such as polyphenylene sulfide (PPS), overmold epoxies doped with boron nitride, alumina, carbon nanotubes, and/or diamond-like thermal additives.

In some embodiments, molding layer 110 may include a first portion 110-1 and a second portion 110-2. First portion 110-1 may be direct over MEMS device layer 108 and underneath routing layer 124, encapsulating second conductive vias 114. The side surface of first portion 110-1 may align with the side surface of MEMS device layer 108. Second portion 110-2 may surround and encapsulate first portion 110-1 and MEMS device 126, encapsulating first conductive vias 112. For case of illustration, the boundary between first portion 110-1 and second portion 110-2 is depicted in dash lines. In some embodiments, first portion 110-1 and second portion 110-2 may include different types of molding compounds, and the boundary may be visible. For example, first portion 110-1 and second portion 110-2 may include molding compounds of different thermal conductivities. In some embodiments, first portion 110-1 and second portion 110-2 may include the same or similar molding compound(s), and the boundary may not be visible.

First conductive via 112 may be located aside from MEMS device 126 and may extend through molding layer 110. An upper surface of first conductive via 112 may be coplanar with the upper surface of molding layer 110, and a lower surface of first conductive via 112 may be in contact with controlling device layer 122. In some embodiments, first conductive via 112 may be conductively connected to the controller component in controlling device layer 122.

Second conductive via 114 may be located over MEMS device 126 and may extend through molding layer 110. An upper surface of second conductive via 114 may be coplanar with the upper surface of molding layer 110, and a lower surface of second conductive via 114 may be in contact with MEMS device layer 108. In some embodiments, second conductive via 114 may be conductively connected to the MEMS component in MEMS device layer 108. In some embodiments, first conductive via 112 and second conductive via 114 may each include a suitable conductive material such as copper (Cu), tungsten (W), aluminum copper (AlCu), molybdenum (Mo), titanium nitride (TiN), gold (Au), and/or platinum (Pt)).

Routing layer 124 may be disposed over (e.g., on) the upper surface of molding layer 110. Routing layer 124 may include one or more conductive routing components 116 disposed in an insulating layer 118. Conductive routing components 116 may redistribute or direct signals to a desired location for electrical transmission and/or physical bonding. Routing layer 124 (or conductive routing components 116) may function as input/output (I/O) ports of package 100. In some embodiments, conductive routing component 116 provides electrical connection between a first conductive via 112 and a second conductive via 114 to jointly transmit/conduct the control signal and the RF signal. In some embodiments, conductive routing component 116 is conductively connected to (e.g., be in contact with) only first conductive via(s) 112 or only second conductive via(s) 114 to separately transmit/conduct the respective signal (control signal or RF signal). Conductive routing components 116 may be located in different elevations/layers in insulating layer 118, in the z-direction. In some embodiments, routing layer 124 is referred to as a redistribution layer. Conductive routing component 116 may include a suitable conductive material such as copper (Cu), tungsten (W), aluminum copper (AlCu), molybdenum (Mo), titanium nitride (TiN), gold (Au), and/or platinum (Pt)). Insulating layer 118 may be a multi-layer structure that includes a suitable dielectric material such as silicon oxide, silicon nitride, and/or silicon oxynitride, or other suitable insulating materials such as glass, resin, etc.

Soldering feature 120 may be disposed in contact with conductive routing component 116. In some embodiments, soldering feature 120 can be conductively connected to a conductive routing component 116 that conducts both the RF signal and/or the control signal, or connect to a conductive routing component 116 that conducts only the RF signal or the control signal. Soldering features 120 may be further coupled to an external circuit. In some embodiments, soldering features 120 include a suitable conductive material such as (Sn), silver (Ag), lead (Pb), nickel (Ni), copper, and/or SnAgCu.

The dimensions and spacings of first conductive vias 112 and second conductive vias 114 may be optimized to reduce interference between the RF signal and the surroundings (such as the control signal or silicon material) and the electrical resistance of first conductive vias 112 and second conductive vias 114. In some embodiments, a ratio between a vertical dimension (e.g., height) h1 and a lateral dimension d1 (e.g., diameter) of first conductive via 112 is about 1:1. In some other embodiments, the ratio between h1 and d1 is about 2:1. In some embodiments, d1 is between about 50 μm and about 90 μm, such as 75 μm. In some embodiments, a ratio between a vertical dimension (e.g., height) h2 and a lateral dimension d2 (e.g., diameter) of second conductive via 114 is about 1:1. In some embodiments, d1 is between about 40 μm and about 80 μm, such as 60 μm. In some embodiments, h2 is between about 10 μm and about 70 μm, such as 30 μm. A distance between the two first conductive vias 112 may be p1, and a distance between the two second conductive vias 114 may be p2. In some embodiments, a ratio between distance p1 and height h1 is about 2:1. For example, d1 may be about 75 μm, and p1 may be about 150 μm. In some embodiments, h1 is between about 80 μm and about 120 μm, such as 100 μm. In some embodiments, a ratio between a distance p2 (e.g., the distance between two second conductive vias 114) and height h2 is about 2:1. In some embodiments, a total thickness h3, e.g., from the top surfaces of soldering features 120 to the bottom surface of base layer 102, may be between about 400 μm and about 600 μm, such as about 500 μm. In some embodiments, a distance 11 between first conductive via 112 and the closest MEMS device 126 is between about 50 μm and about 100 μm, e.g., about 65 μm.

Package 100 may reduce the non-linearity of the RF signal by routing the RF signal directly from MEMS device 126 to the external circuit, compared to an existing package in which the RF signal is routed from the MEMS chip to the controller, and from the controller to the external circuit. In package 100, the RF signal is transmitted directly from the upper surface of MEMS device 126 to soldering feature 120, and does not need to travel between controller device 128 and routing layer 124. The routing distance of RF signal is reduced, and the RF signal is less susceptible to interference from the surroundings. Depending on the design, the RF signal and the control signal from controller device 128 can be transmitted to routing layer 124 separately or jointly, further reducing the potential interference on the RF signal (or the control signal) as needed. Further, MEMS device 126 and controller device 128 are coupled to each other by adhesive layer 104, which is cheaper in material and makes the placement (e.g., alignment) of MEMS device 126 during fabrication easier. For example, soldering is needed for the coupling of MEMS device 126 and controller device 128.

FIG. 1B illustrates another package 130, according to some embodiments. Different from package 100, package 130 includes a MEMS device 127 that has a base layer 105. Different from base layer 106, base layer 105 may include a molding compound. In some embodiments, base layer 105 may have a low dielectric constant less than 8, or between 3 and 5 to yield low radio frequency (RF) coupling. Base layer 105 may include molding epoxy, a nitride such as silicon nitride, an oxide such as silicon oxide, phosphosilicate glass (PSG), borosilicate glass (BSG), boron-doped phosphosilicate glass (BPSG), phenolic hardener, silica, pigment, and/or a combination thereof. Base layer 106 may also include thermoplastics or thermoset polymer materials, such as polyphenylene sulfide (PPS), overmold epoxies doped with boron nitride, alumina, carbon nanotubes, and/or diamond-like thermal additives. In some embodiments, base layer 105 has a thermal conductivity between about 2.0 W/m·K and about 6600 W/m·K.

FIG. 1C illustrates another package 150, according to some embodiments. Different from packages 100 and 130, package 150 includes a controller device 136 that has a base layer 132. Different from base layer 102, base layer 132 may include a molding compound. Base layer 132 may be positioned at the lower surface (e.g., lower surface) of controlling device layer 122, e.g., an upper surface (e.g., upper surface) of base layer 132 may be coupled to the lower surface of controlling device layer 122. Base layer 132 may provide support to controlling device layer 122 and may have desirably high stiffness and thermal conductivity, and low interference to controlling device layer 122. In some embodiments, base layer 132 includes a molding compound. In some embodiments, base layer 132 may have a thermal conductivity between about 2.0 W/m·K and about 6600 W/m·K. In some embodiments, base layer 132 may have a low dielectric constant less than 8, or between 3 and 5 to yield low radio frequency (RF) coupling. Base layer 132 may include thermoplastics or thermoset polymer materials, such as polyphenylene sulfide (PPS), over-mold epoxies doped with boron nitride, alumina, carbon nanotubes, and/or diamond-like thermal additives, or the like substrate.

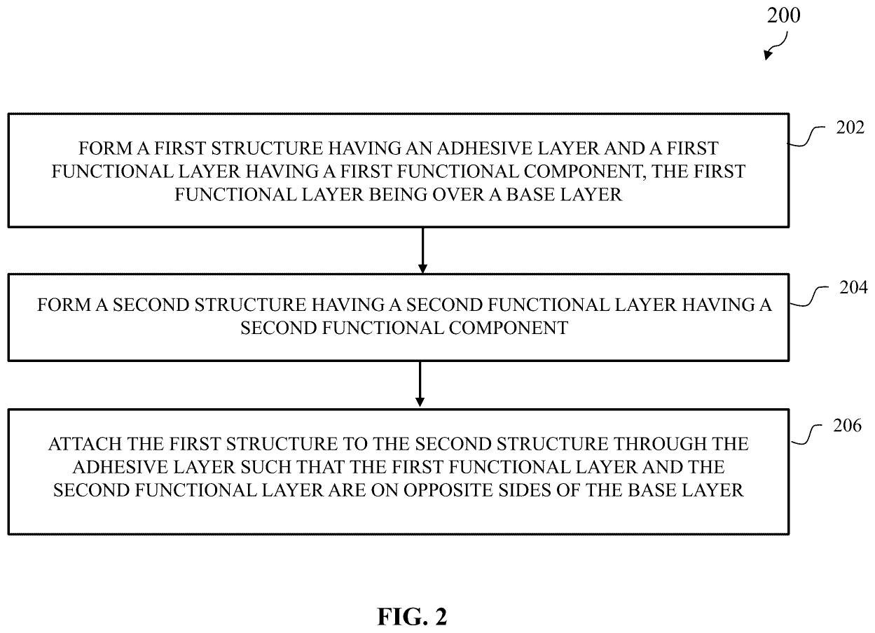

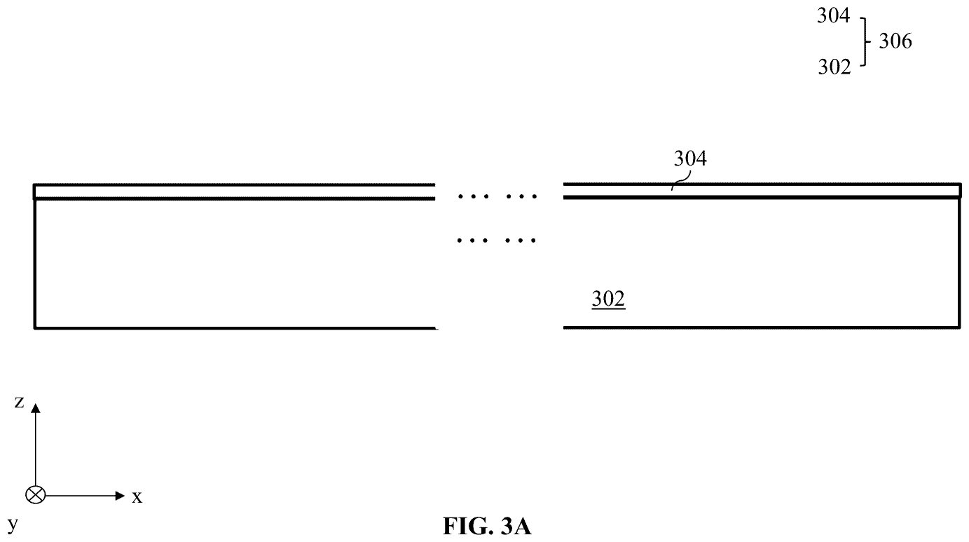

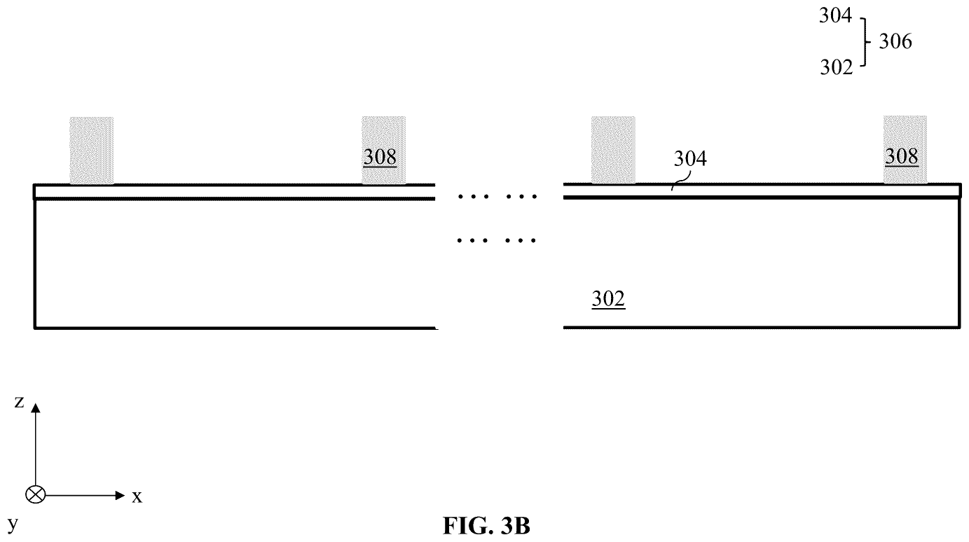

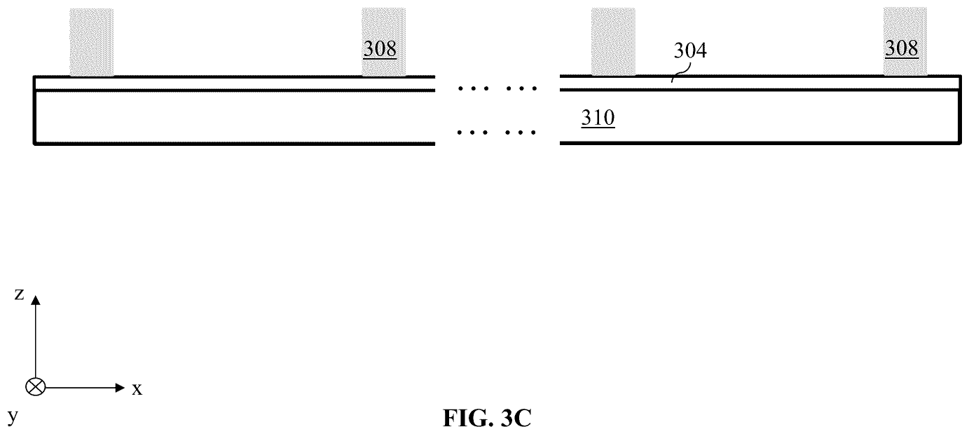

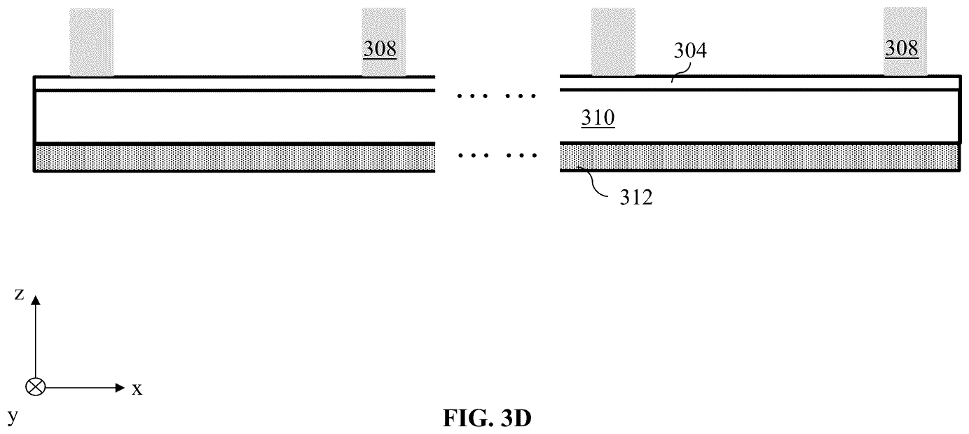

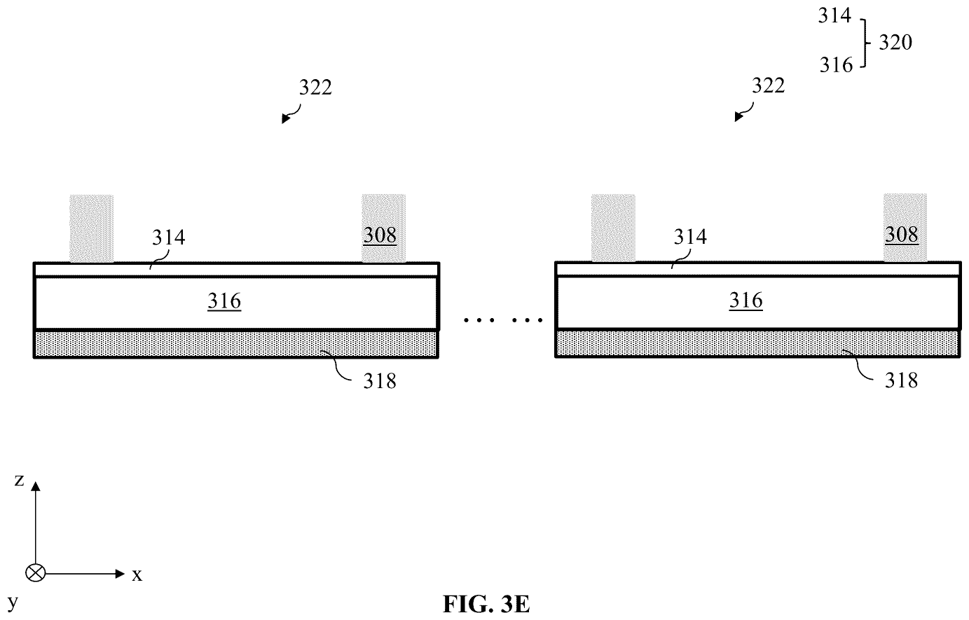

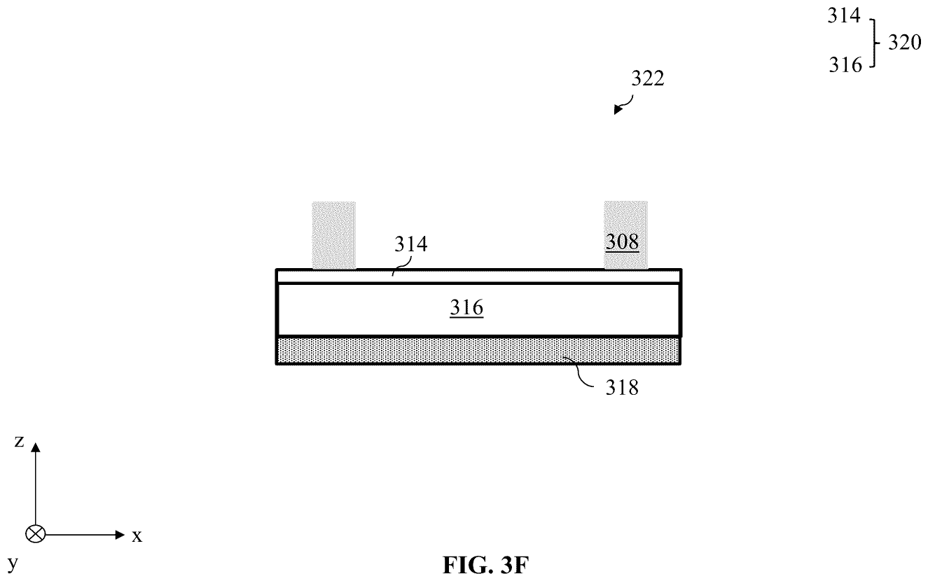

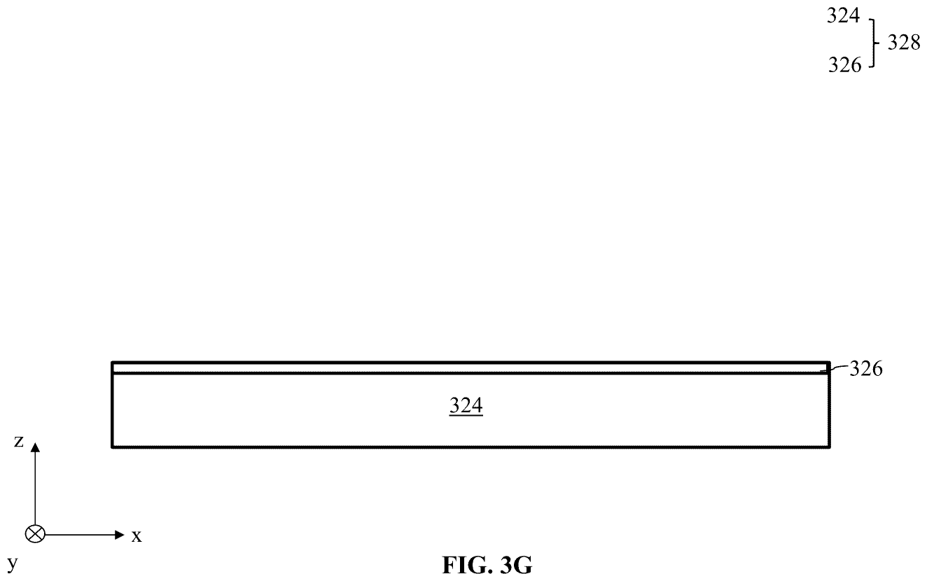

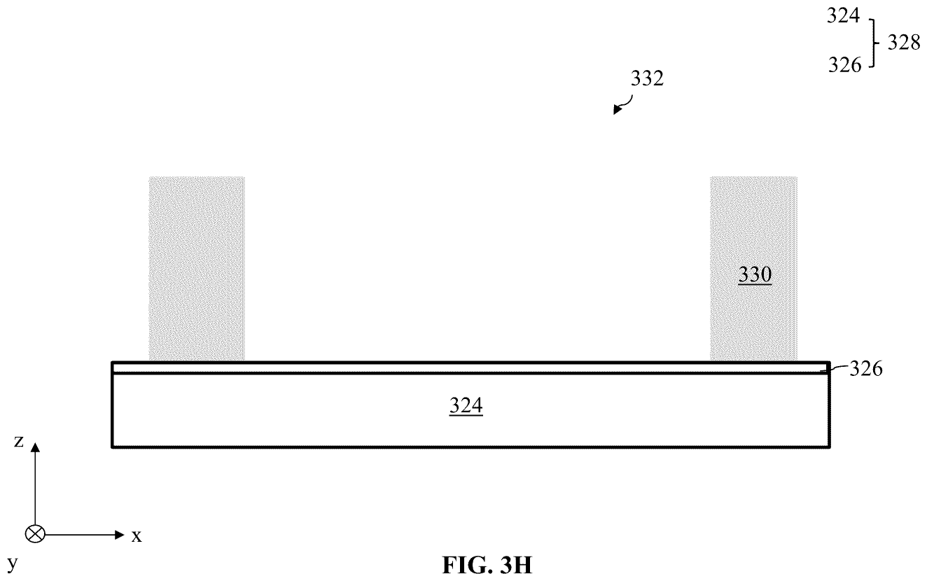

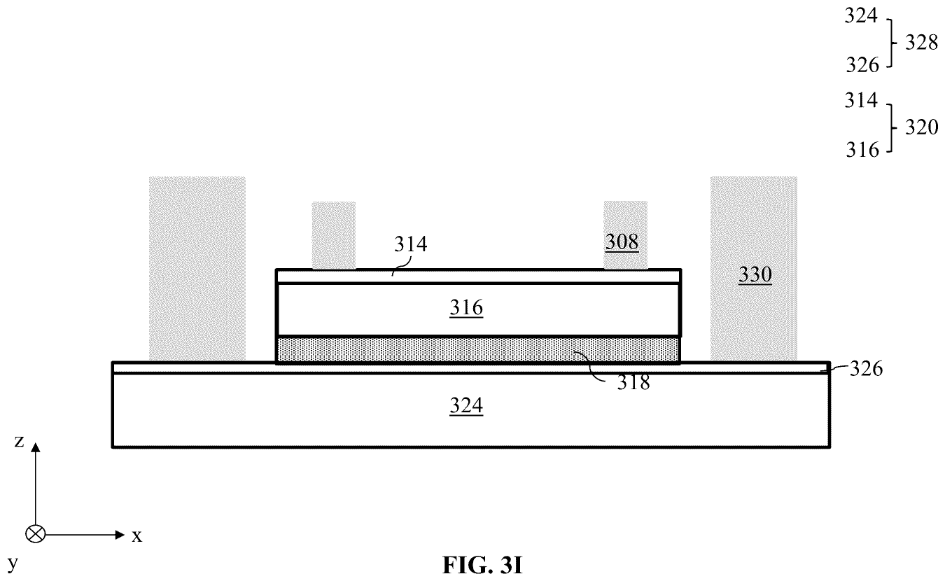

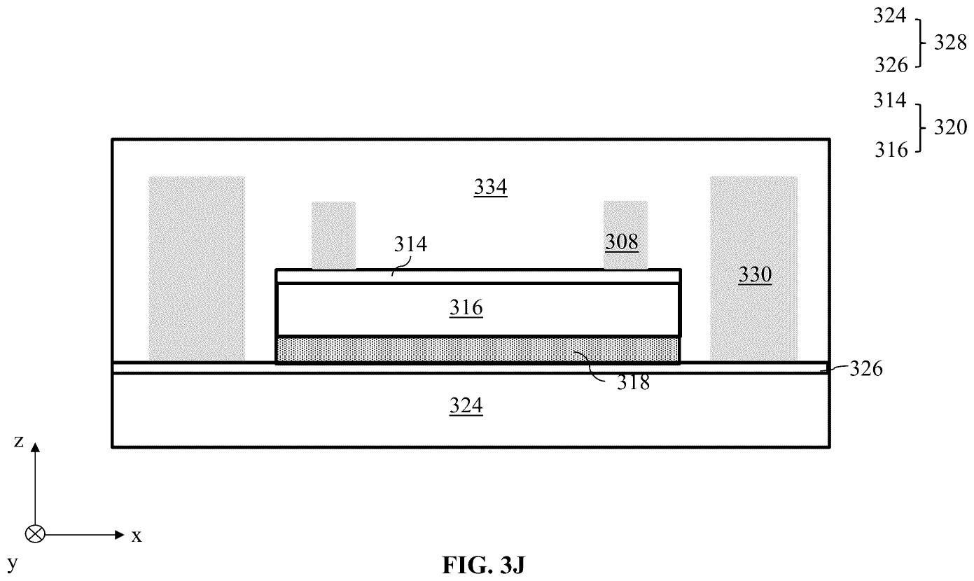

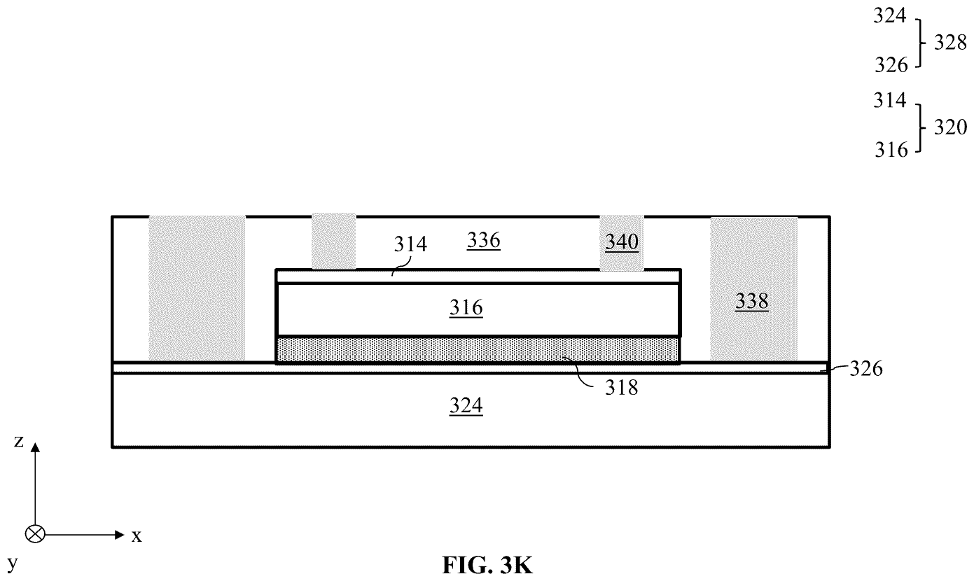

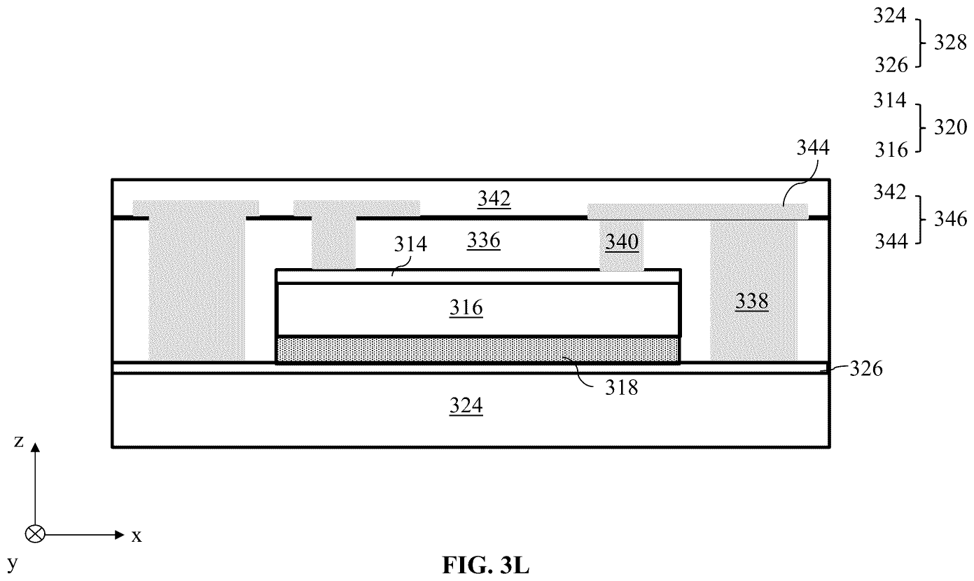

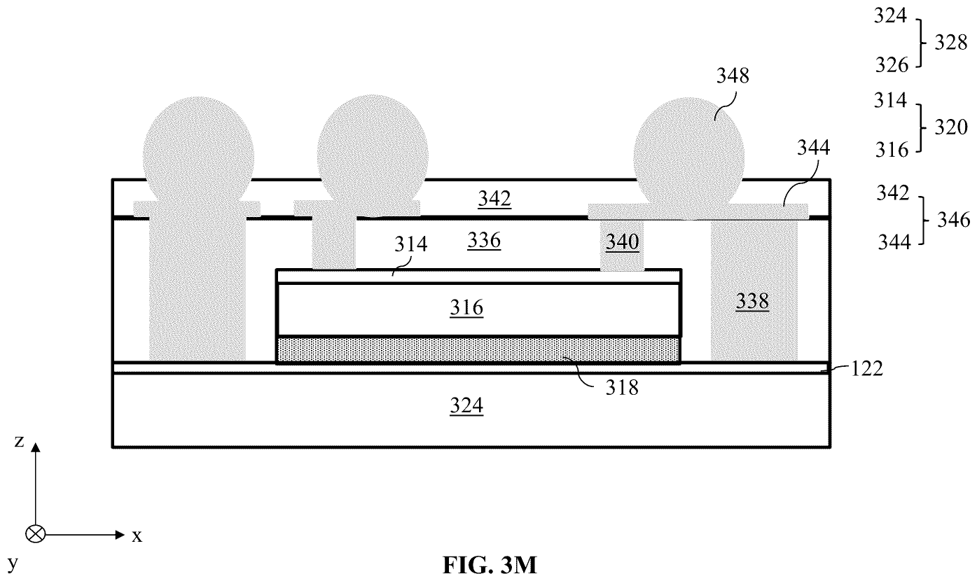

FIG. 2 is a flowchart of a method 200 for forming a package, according to some embodiments of the present disclosure. Method 200 is merely an example, and is not intended to limit the present disclosure beyond what is explicitly recited in the claims. Additional operations can be provided before, during, and after the method 200, and some operations described can be replaced, eliminated, or moved around for additional embodiments of method 200. Method 200 will be described in more detail below. FIGS. 3A-3M illustrate structures of the package at different stages of a fabrication process. In various embodiments, method 200 may be used to form package 100. In some embodiments, package 100 formed by the process shown in FIGS. 3A-3M may include a molding layer that has the same material over and around the first device, e.g., with no separation of the molding layer to a first portion and a second portion. For case of illustration, method 200 may be described in connection with FIGS. 1A-IC when necessary.

At step 202, a first structure is formed. The first structure includes an adhesive layer and a first functional layer that includes a first functional component. The first functional layer is over a base layer. In some embodiments, the first functional structure includes a MEMS structure, the first functional layer includes a MEMS device layer, and the first functional component includes a MEMS component. FIGS. 3A-3F illustrate corresponding structures.

As shown in FIG. 3A, a first material layer 306 is provided. First material layer 306 may also be referred to as a MEMS wafer. First material layer 306 may include a base material layer 302 and a first device material layer 304 (e.g., a MEMS device material layer) disposed on an upper surface of base material layer 302. Base material layer 302 may include a similar material as base layer 106 of FIG. 1A. In some embodiments, base material layer 302 includes silicon. First device material layer 304 may include one or more MEMS components configured to interact with RF signals. The MEMS components can include any suitable devices and/or structures such as sensors, switches, resonators, etc. first device material layer 304 may also include various metallization layers, conductive vias, and/or dielectric layers for the processing and transmission of the RF signals. For example, each MEMS component in first device material layer 304 is coupled with a plurality of conductive vias, metallization layers, and/or dielectric layers such that each MEMS component can function as an individual device. The forming of first device material layer 304 may include forming one or more back-end-of-line (BEOL) structures/devices, one or more middle-end-of-line (MEOL) structures/devices, one or more front-end-of-line (FEOL) structures/devices. In some embodiments, first device material layer 304 includes a redistribution layer formed over the MEMS components. The redistribution layer may be electrically connected to the MEMS components and may include ends exposed at desired locations for connections to conductive via structures (e.g., 308). The fabrication of first material layer 306 may include photolithography, dry etch, wet etch, chemical vapor deposition (CVD), physical vapor deposition (PVD), atomic layer deposition (ALD), electroplating, electroless plating, soldering, grinding, chemical mechanical polishing (CMP), or a combination thereof.

As shown in FIG. 3B, one or more conductive via structures 308 may be formed on the upper surface of first device material layer 304 (or the upper surface of first material layer 306). In some embodiments, each MEMS component in first device material layer 304 is conductively connected to a respective conductive via structures 308. In some embodiments, conductive via structures 308 are formed using plating, such as electroplating and/or electroless plating, e.g., to a desired thickness, such as at least 50 μm. In some embodiments, the formation of conductive via structures 308 include photolithography, dry etch, wet etch, chemical vapor deposition (CVD), physical vapor deposition (PVD), atomic layer deposition (ALD), or a combination thereof. The height of conductive via structure 308 may be higher than the final conductive via (e.g., second conductive via 114) for a grinding margin. For example, conductive via structure 308 may be about 65 μm in the z-direction. In some embodiments, the formation of conductive via structure 308 includes forming an under bump metallization (UBM) in first device material layer 304, and a metal (e.g., copper) pillar in contact with the UBM.

As shown in FIG. 3C, first material layer 306 may be thinned at the back side, e.g., by removing part of base material layer 302 at its lower surface to a desired thickness. In some embodiments, the thinning of base material layer 302 includes grinding, wet etch, dry etch, and/or CMP. Thinned base material layer 310 may be formed. In some embodiments, thinned base material layer 310 may have a thickness of about 50 μm.

As shown in FIG. 3D, an adhesive material layer 312 is attached at the lower surface of thinned base material layer 310. In some embodiments, adhesive material layer 312 includes epoxy and can be formed by spin-on coating (e.g., followed by a curing process). In some embodiments, adhesive material layer 312 includes an adhesive tape that can be glued directly on thinned base material layer 310. In some embodiments, the attaching of adhesive material layer 312 includes applying heat and/or pressure on adhesive material layer 312 and thinned base material layer 310.

As shown in FIGS. 3E and 3F, thinned base material layer 310, first device material layer 304, and adhesive material layer 312, with conductive via structures 308, may be diced into a plurality of first structures 322 (e.g., MEMS structures). Specifically, first device material layer 304 may be diced into a plurality of first device layers 314 (e.g., MEMS device layers or first functional layers), thinned base material layer 310 may be diced into a plurality of base layers 316, and adhesive material layer 312 may be diced into a plurality of adhesive layers 318. Each first structure 322 may include a first device layer 314 on an upper surface of a base layer 316, and an adhesive layer 318 on a lower surface of base layer 316. First structure 322 may also include at least one MEMS component, and one or more conductive via structures 308 conductively connected to the corresponding MEMS component(s). first device layer 314 and base layer 316 may form a first device 320 (e.g., a MEMS device).

Referring back to FIG. 2, at step 204, a second structure is formed. The second structure may be a controller structure. The second structure may include a second device layer (e.g., a controlling device layer or a second functional layer) having a second functional component (e.g., a controller component). FIGS. 3G and 3H illustrate corresponding structures. It should be noted that, the controller structure formed in FIGS. 3G and 3H may also be used in the forming of other exemplary packages of this disclosure.

As shown in FIG. 3G, a second device 328 (e.g., a controller device) is provided. Controller device 328 may include a base layer 324 and a second device layer 326 (e.g., a controlling device layer or a second functional layer) disposed on an upper surface of base layer 324. Second device layer 326 may include at least one controller component configured to generate a control signal for the controlling of the first functional component. Base layer 324 may include silicon, molding compound, or the like. The forming of second device layer 326 may include forming one or more back-end-of-line (BEOL) structures/devices, one or more middle-end-of-line (MEOL) structures/devices, one or more front-end-of-line (FEOL) structures/devices. In some embodiments, the fabrication of second device 328 may include photolithography, dry etch, wet etch, chemical vapor deposition (CVD), physical vapor deposition (PVD), atomic layer deposition (ALD), electroplating, electroless plating, soldering, grinding, chemical mechanical polishing (CMP), spin-on coating, curing, or a combination thereof.

In some embodiments, second device material layer 326 includes a redistribution layer formed over the controller component. The redistribution layer may be electrically connected to the controller component and may include ends exposed at desired locations for connections to conductive via structures (e.g., 330).

As shown in FIG. 3H, one or more conductive via structures 330 may be formed on the upper surface of second device layer 326 (or the upper surface of second device 328). In some embodiments, the controller component in second device layer 326 is conductively connected to one or more conductive via structures 330. In some embodiments, conductive via structures 330 are formed using plating, such as electroplating and/or electroless plating, e.g., to a desired thickness, such as at least 100 μm. In some embodiments, the formation of conductive via structures 330 include photolithography, dry etch, wet etch, chemical vapor deposition (CVD), physical vapor deposition (PVD), atomic layer deposition (ALD), or a combination thereof. In some embodiments, conductive via structure 330 includes a metal (e.g., copper) pillar. A second structure 332, including second device 328 and conductive via structures 330, may be formed.

Referring back to FIG. 2, at step 206, the first structure is attached to the second structure through the adhesive layer such that the first device layer (e.g., first functional layer) and the second device layer (e.g., second functional layer) are on opposite sides of the base layer of the first structure. FIGS. 3I-3M illustrate corresponding structures.

As shown in FIG. 3I, first structure 322 may be attached to second structure 332 through adhesive layer 318. The lower surface of adhesive layer 318 may be attached to the upper surface of second structure 332 (or the upper surface of second device layer 326) such that first device layer 314 and second device layer 326 are on opposite sides of base layer 316 (e.g., being attached to base layer 316 by adhesives). In other words, first device 320 has a “face-up” configuration, e.g., facing towards the same direction.

As shown in FIG. 3J, a molding material layer 334 is formed over second device 328. Molding material layer 334 may encapsulate conductive via structures 330 and 308, adhesive layer 318, and first device 320. In some embodiments, molding material layer 334 includes a molding compound, and is formed by depositing a layer of molding material, which can then be cured to harden. In some embodiments, molding material layer 334 may fill any gap between base layer 316 and the upper surface of second structure 332 such that molding material layer 334 may be disposed between base layer 316 and the upper surface of second structure 332.

As shown in FIG. 3K, molding material layer 334 and conductive via structures 330 and 308 may be planarized to form a molding layer 336, one or more first conductive vias 338, and one or more second conductive vias 340, respectively. In some embodiments, the upper surfaces of first conductive vias 338 and second conductive vias 340 are coplanar with the upper surface of molding layer 336. In other words, first conductive vias 338 and second conductive vias 340 may be exposed. In some embodiments, the planarization includes a grinding process, a suitable etching process (e.g., wet etch and/or dry etch), and/or CMP.

As shown in FIG. 3L, a routing layer 346 may be formed on the upper surfaces of molding layer 336, first conductive vias 338, and second conductive vias 340. Routing layer 346 may include one or more conductive routing components 344 embedded in an insulating layer 342. The one or more conductive routing components 344 may be conductively connected to first conductive via 338 and/or second conductive via 340. For example, conductive routing component 344 may conductively connect a first conductive via 338 and a second conductive via 340. In another example, conductive routing component 344 may route first conductive via 338 and/or second conductive via 340 to a desired location for the subsequent formation of soldering features. In some embodiments, conductive routing component 344 includes a conductive material, and insulating layer 342 includes a dielectric material. The formation of routing layer 346 may include photolithography, dry etch, wet etch, chemical vapor deposition (CVD), physical vapor deposition (PVD), atomic layer deposition (ALD), electroplating, electroless plating, soldering, grinding, chemical mechanical polishing (CMP), or a combination thereof.

As shown in FIG. 3M, one or more soldering features 348 may be formed to be conductively connected to one or more conductive routing components 344. In some embodiments, soldering feature 348 may include a conductive material such as tin (Sn). The formation of soldering feature 348 may include photolithography, dry etch, wet etch, solder ball drop, and thermal reflow.

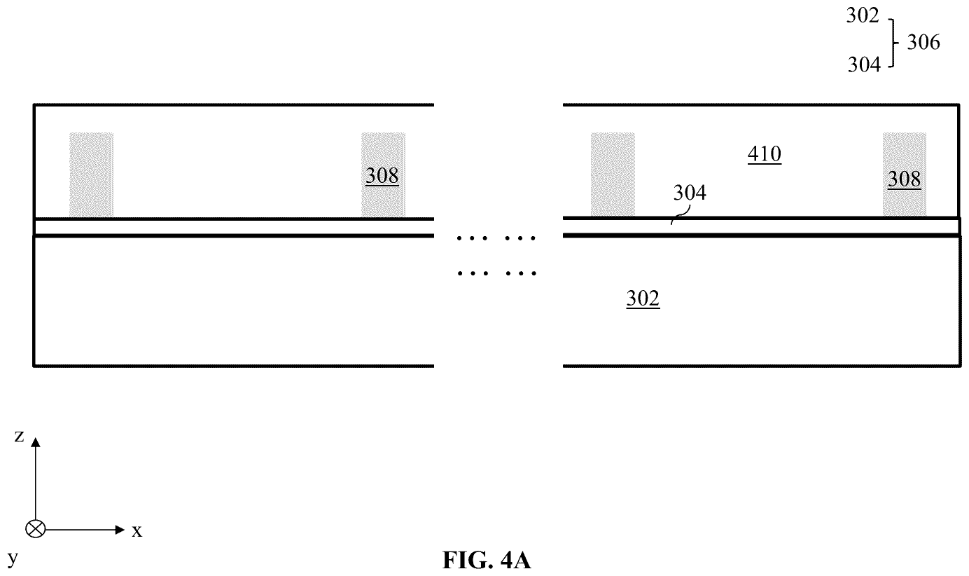

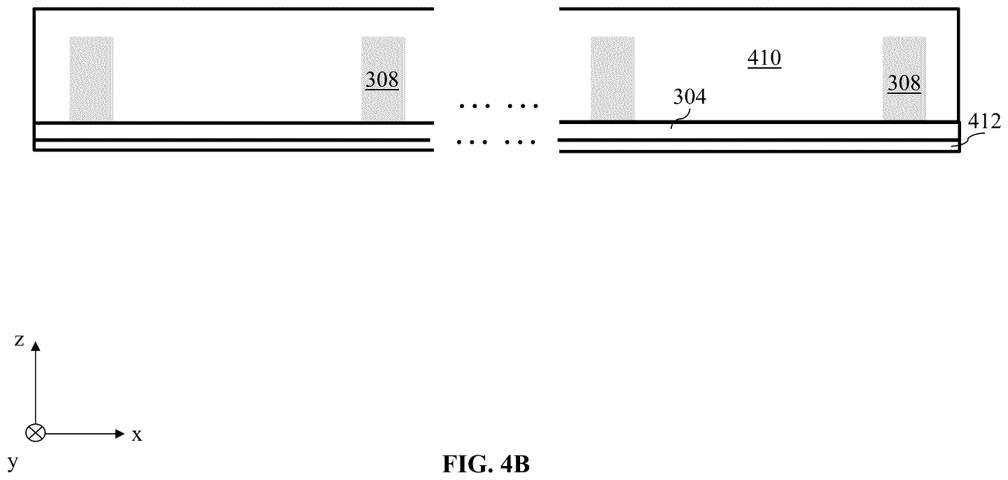

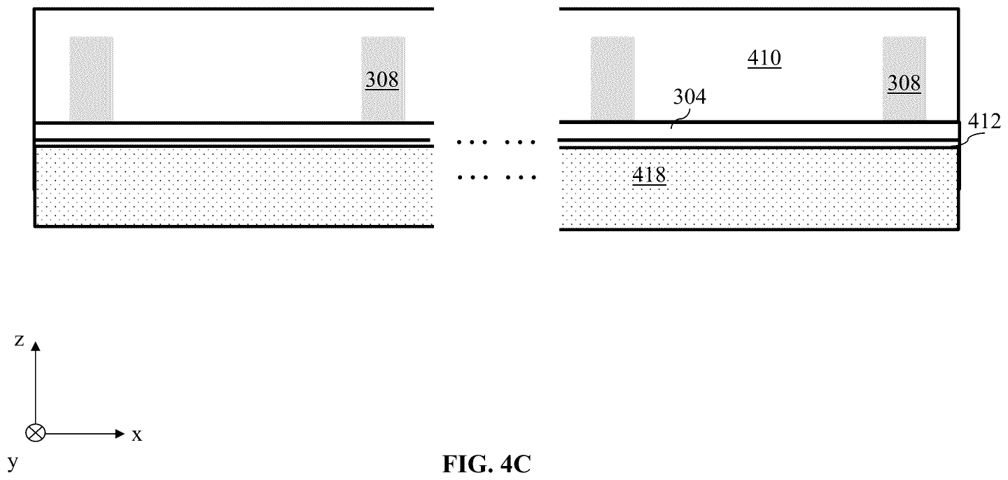

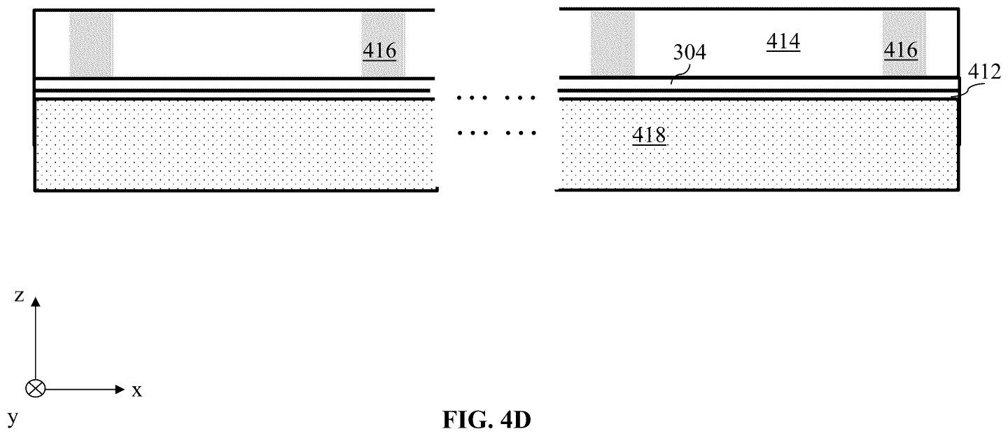

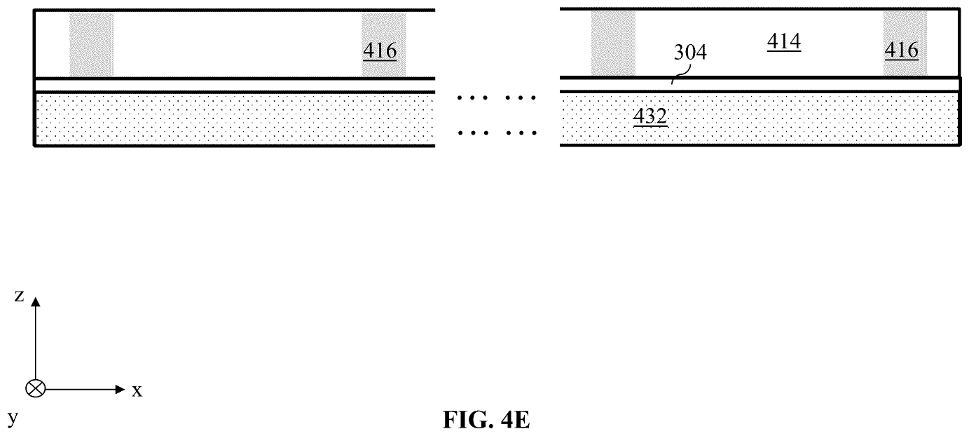

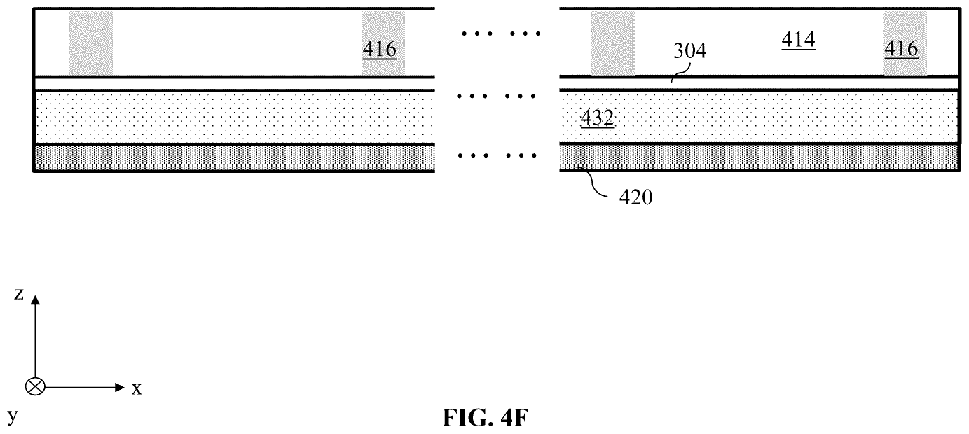

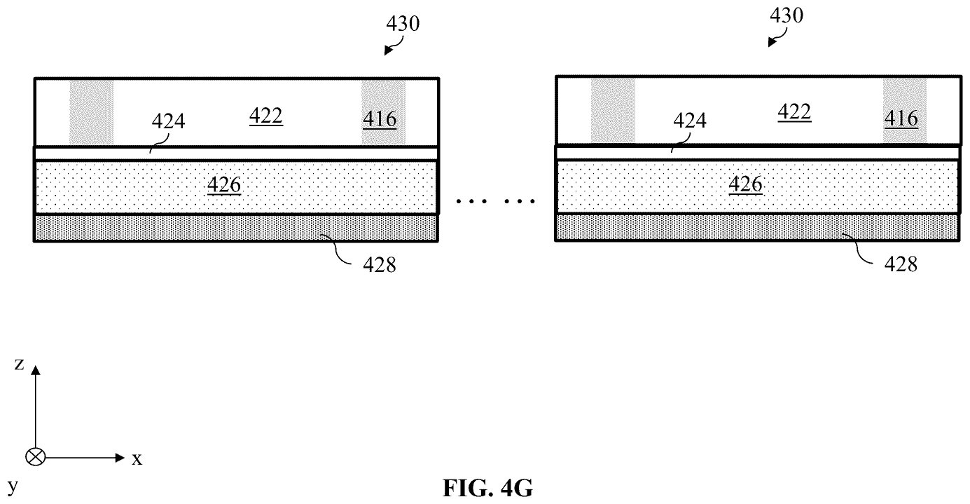

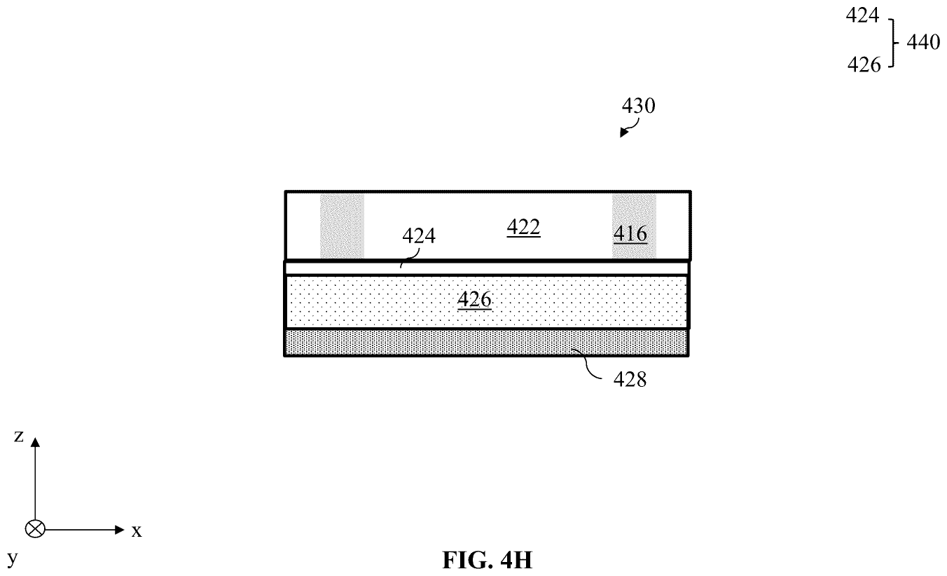

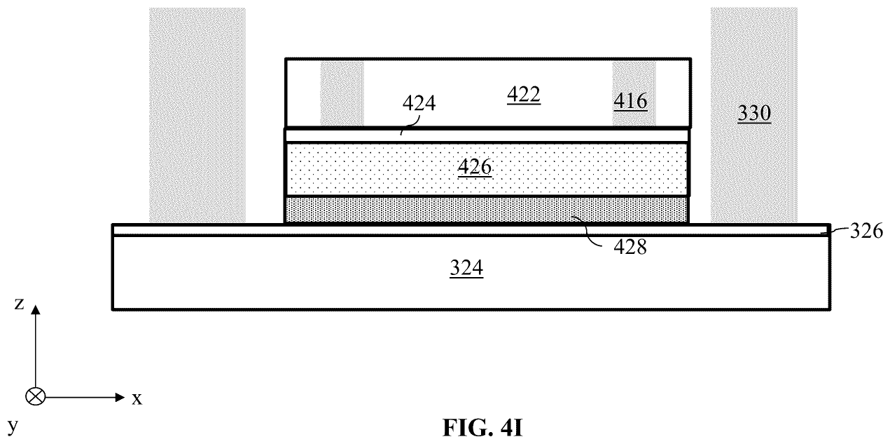

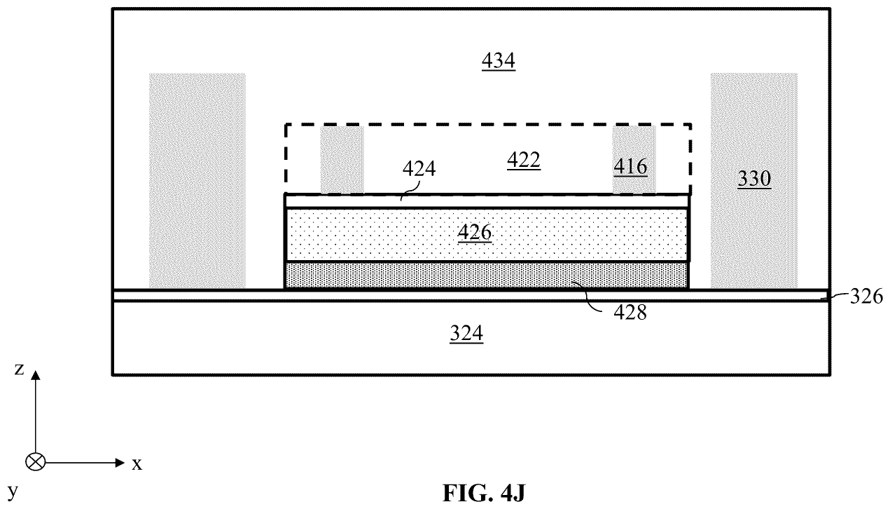

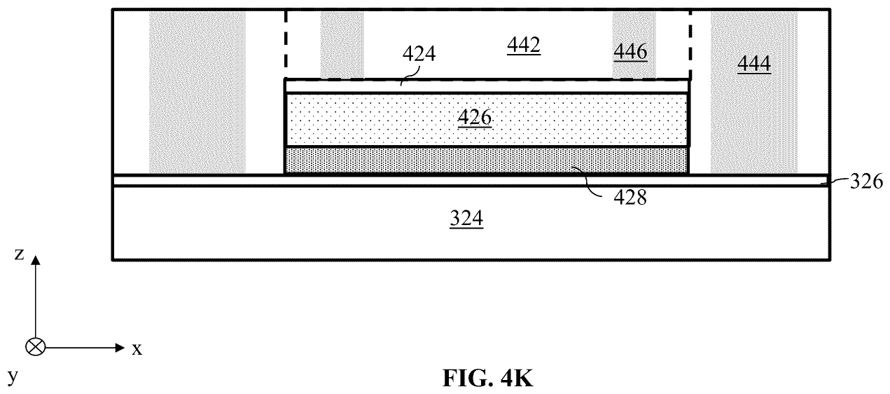

FIGS. 4A-4K illustrates part of a process to form another package using method 200, according to some embodiments. In various embodiments, the process in FIGS. 4A-4K may be used to form package 130. For case of illustration, method 200 may be described in connection with FIGS. 1A-IC.

At step 202, a first structure is formed. The first structure includes an adhesive layer and a first device layer (e.g., a first functional layer) that includes a functional component (e.g., a MEMS component). The first device layer is over a base layer. FIGS. 4A-4H illustrate corresponding structures.

As shown in FIGS. 4A, a first material layer 306 is provided, and one or more conductive via structures 308 are formed on first material layer 306. First material layer 306 may include a base material layer 302 and a first device material layer 304 over base material layer 302. The structure shown in FIG. 4A may be formed after the structure shown in FIG. 3B. The materials and fabrication method of first material layer 306 and conductive via structures 308 can be referred to the description of FIGS. 3A and 3B, and is not repeated herein. A molding material layer 410 is formed on first material layer 306. Molding material layer 410 may encapsulate conductive via structures 308. In some embodiments, molding material layer 410 includes a molding compound, and is formed by depositing a layer of molding material, which can then be cured to harden.

As shown in FIG. 4B, base material layer 302 may be thinned at the back side to a desired thickness. A thinned base material layer 412 may be formed. In some embodiments, the thinning of base material layer 302 includes grinding, wet etch, dry etch, and/or CMP. In some embodiments, base material layer 302 may include an etch stop layer, such as a silicon oxide layer disposed underneath first device material layer 304 to stop the etching/grinding.

As shown in FIG. 4C, a second base material layer 418 may be disposed over thinned base material layer 412. In some embodiments, thinned base material layer 412 (or base material layer 302) includes a non-molding material, such as silicon, and second base material layer 418 includes a molding compound, which has lower RF coupling than the non-molding material. A molding material may be deposited onto the lower surface of thinned base material layer 412 by depositing a layer of the molding material, which can then be cured to harden.

As shown in FIG. 4D, molding material layer 410 and conductive via structures 308 may be planarized to form a first molding layer 414 and one or more conductive via structures 416, respectively. Conductive via structures 416 may be exposed. In some embodiments, the upper surfaces of conductive via structures 416 are coplanar with the upper surface of first molding layer 414. In some embodiments, the planarization includes a grinding process, a suitable etching process (e.g., wet etch and/or dry etch), and/or CMP.

As shown in FIG. 4E, second base material layer 418 may be planarized to form a thinned second base material layer 432. In some embodiments, thinned second base material layer 432 has a thickness of about 50 μm. In some embodiments, the planarization includes a grinding process, a suitable etching process (e.g., wet etch and/or dry etch), and/or CMP.

As shown in FIG. 4F, an adhesive material layer 420 is attached at the lower surface of thinned second base material layer 432. In some embodiments, adhesive material layer 420 includes epoxy and can be formed by spin-on coating (e.g., followed by a curing process). In some embodiments, adhesive material layer 420 includes an adhesive tape that can be glued directly on thinned second base material layer 432. In some embodiments, the attaching of adhesive material layer 420 includes applying heat and/or pressure on adhesive material layer 420 and thinned second base material layer 432.

As shown in FIGS. 4G and 4H, first device material layer 304, thinned second base material layer 432, and adhesive material layer 420, with conductive via structures 416 and first molding layer 414, may be diced into a plurality of first structures 430 (e.g., MEMS structures). Specifically, first device material layer 304 may be diced into a plurality of first device layers 424 (e.g., first functional layers), thinned second base material layer 432 may be diced into a plurality of base layers 426, adhesive material layer 420 may be diced into a plurality of adhesive layers 428, and first molding layer 414 may be diced into a plurality of second molding layers 422. Each first structure 430 may include a first device layer 424 on an upper surface of base layer 426, a second molding layer 422 encapsulating conductive via structures 416 on the respective first device layer 424, and adhesive layer 428 on a lower surface of base layer 426. First structure 430 may also include at least one first functional component (e.g., a MEMS component), and one or more conductive via structures 416 are conductively connected to the corresponding MEMS component(s). first device layer 424 and base layer 426 may form a first device 440 (e.g., MEMS device 440).

Referring back to FIG. 2, at step 204, a second structure is formed. The second structure may include a second device layer (e.g., second functional layer) having a second functional component (e.g., second controller component). FIGS. 3G and 3H illustrate corresponding structures. The formation of second structure 332 can be referred to the description of FIGS. 3G and 3H, and the detailed description is not repeated herein.

Referring back to FIG. 2, at step 206, the first structure is attached to the second structure through the adhesive layer such that the first device layer and the second device layer are on opposite sides of the base layer of the first structure. FIGS. 4I-4K and 3K-3M illustrate corresponding structures.

As shown in FIG. 4I, first structure 430 may be attached to second structure 332 through adhesive layer 428. The lower surface of adhesive layer 428 may be attached to the upper surface of second structure 332 (or the upper surface of second device layer 326) such that first device layer 424 and second device layer 326 are on opposite sides of base layer 426. In other words, first device 440 has a “face-up” configuration.

As shown in FIG. 4J, a molding material layer 434 is formed over second device 328. Molding material layer 434 may encapsulate conductive via structures 330, conductive via structures 416, adhesive layer 318, first device 440, and second molding layer 422. In some embodiments, molding material layer 434 includes a molding compound, and is formed by depositing a layer of molding material, which can then be cured to harden. In some embodiments, molding material layer 434 may fill any gap between base layer 426 and the upper surface of second structure 332 such that molding material layer 434 may be disposed between base layer 426 and the upper surface of second structure 332. It should be noted that, for case of illustration, dashed lines are used to show the possible interface between molding material layer 434 and second molding layer 422. In practice, the boundary may or may not be visible.

As shown in FIG. 4K, molding material layer 434, conductive via structures 330, second molding layer 422, and conductive via structures 416, may be planarized, similar to the process illustrated in FIG. 3K, to form first conductive vias 444, a third molding layer 442, and second conductive vias 446. The structure shown in FIG. 4K may then be further processed according to FIGS. 3L and 3M. For example, a routing layer may be formed on third molding layer 442, and one or more soldering features may be formed over the routing layer, conductively connected to the routing layer. The detailed description is not repeated herein.

In some embodiments, soldering features 120 may be replaced by, or be used with other suitable connecting structures such as land grid array (LGA) pads, micro-pillars (e.g., copper), etc.

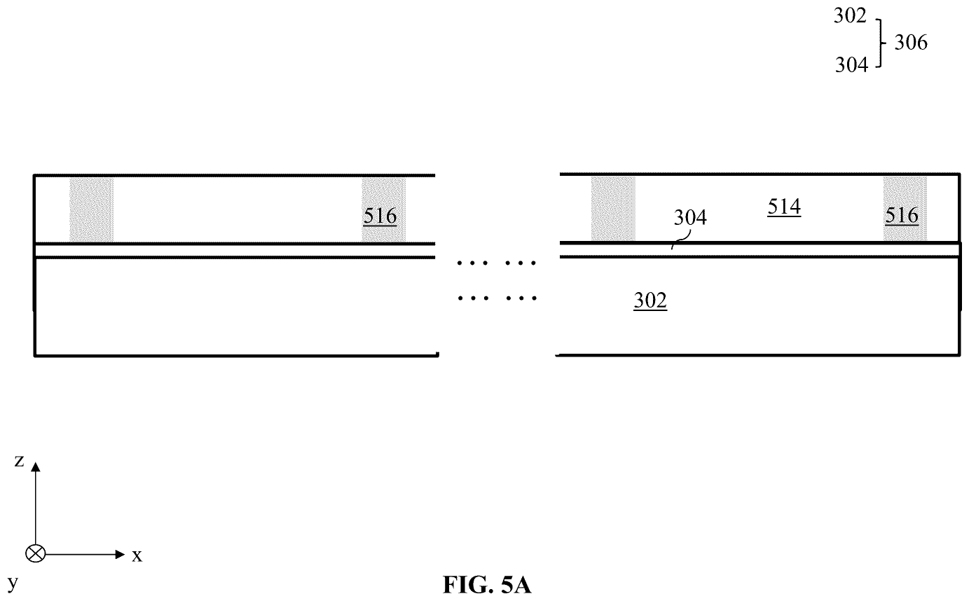

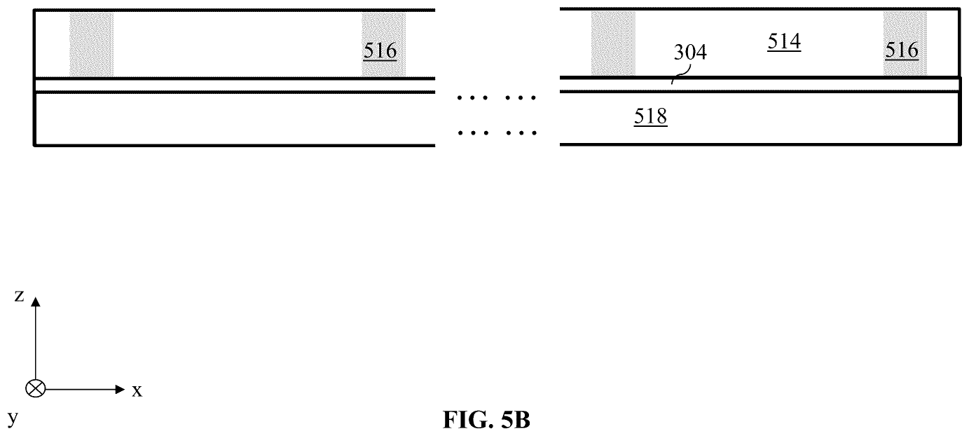

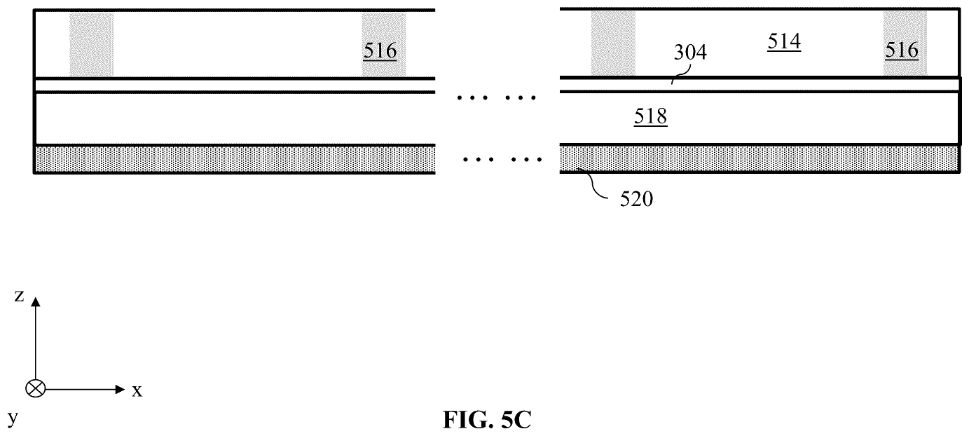

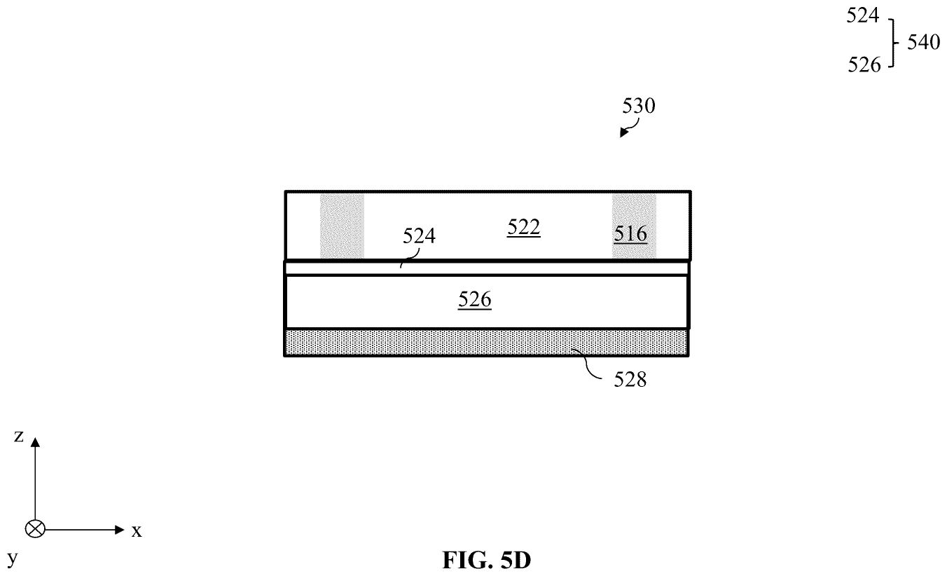

FIGS. 5A-5D illustrate part of an alternative process to form package 100. The process shown in FIGS. 5A-5D may be an alternative of the steps performed in FIGS. 3C-3F. In some embodiments, package 100 formed by the process shown in FIGS. 5A-5D may or may not have a molding layer being separated to a first portion and a second portion.

The structure shown in FIG. 5A may be formed from the same structure depicted in FIG. 4A. As shown in FIG. 5A, molding material layer 410 may be planarized to form a first molding layer 514, and conductive via structures 308 may be planarized to form conductive via structures 516. Conductive via structures 516 may be exposed. The planarization process may be similar to that described in FIG. 4D.

As shown in FIG. 5B, base material layer 302 may be planarized to a desired thickness. In some embodiments, a thinned base material layer 518 can be formed. The planarization process may include grinding, wet etch, dry etch, and/or CMP.

As shown in FIG. 5C, an adhesive material layer 520 is attached at the lower surface of thinned second base material layer 518, similar to the process described in FIG. 4F.

As shown in FIG. 5D, first device material layer 304, thinned second base material layer 518, and adhesive material layer 520, with conductive structures 516 and first molding layer 514, may be diced into a plurality of first structures 530 (e.g., MEMS structures). Specifically, first device material layer 304 may be diced into a plurality of first device layers 524, thinned second base material layer 518 may be diced into a plurality of base layers 526, adhesive material layer 520 may be diced into a plurality of adhesive layers 528, and first molding layer 514 may be diced into a plurality of second molding layers 522. Each first structure 530 may include a first device layer 524 on an upper surface of base layer 526, a second molding layer 522 encapsulating conductive via structures 516 on the respective first device layer 524, and adhesive layer 528 on a lower surface of base layer 526. First structure 530 may also include at least one first functional component (e.g., a MEMS component), and one or more conductive via structures 516 are conductively connected to the corresponding MEMS component(s). First device layer 524 and base layer 526 may form a first device 540. First structure 530 may then be attached to second structure 332, similar to the process described in FIGS. 4I-4K, and the detailed description is not repeated herein.

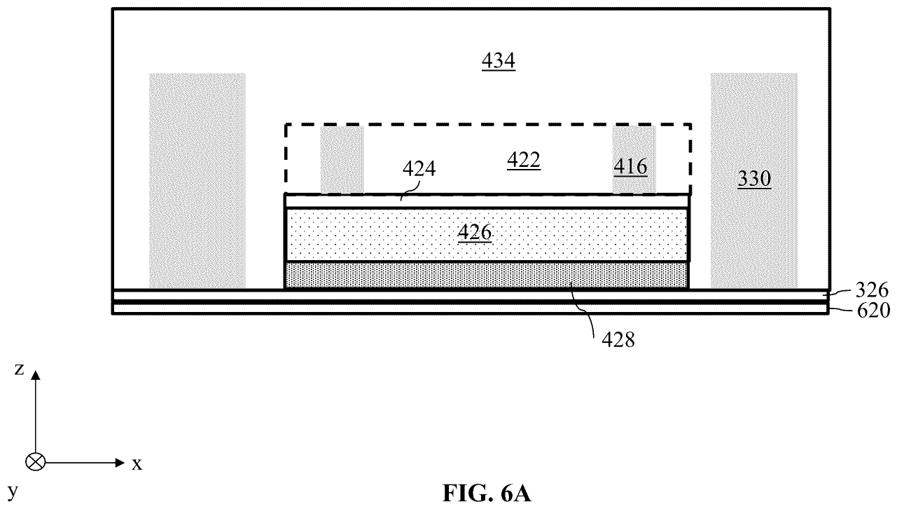

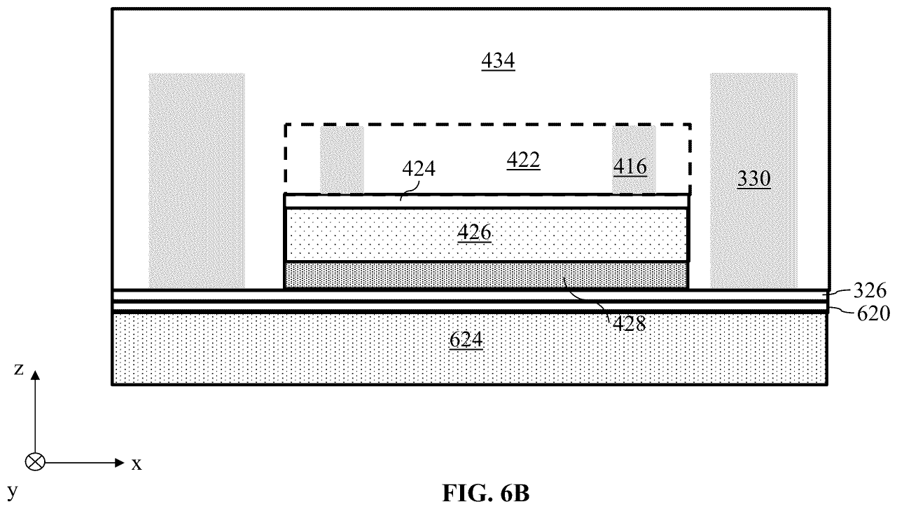

FIGS. 6A and 6B illustrate part of a process to form a package, according to some embodiments. The process shown in FIGS. 6A and 6B may be performed after the structure formed in FIG. 3J or 4J. In some embodiments, the process shown in FIGS. 6A and 6B is performed after the structure of FIG. 4J to form package 150.

As shown in FIG. 6A, base layer 324 may be thinned at the back side to a desired thickness. A thinned base layer 620 may be formed. In some embodiments, the thinning includes grinding, wet etch, dry etch, and/or CMP. In some embodiments, base layer 324 may include an etch stop layer, such as a silicon oxide layer disposed underneath second device layer 326 to stop the etching/grinding.

As shown in FIG. 6B, a second base layer 624 may be disposed over thinned base layer 620. In some embodiments, thinned base layer 620 includes a non-molding material, such as silicon, and second base layer 624 includes a molding compound, which has lower RF coupling than the non-molding material. A molding material may be deposited onto the lower surface of thinned base layer 620 by depositing (e.g., spinning on) a layer of the molding material, which can then be cured to harden.

It should be noted that, second structure 332 can be formed before, at the same time with, or after the forming of first structures 322, 430, and 530. The sequence to form second structure 332 and the respective first structure should not be limited by the embodiments of the present disclosure.

1. A package, comprising:
a first semiconductor device comprising a first functional layer having a first functional component; and
a second semiconductor device over the first semiconductor device, the second semiconductor device comprising a second functional layer having a second functional component, the second functional layer being over a base layer, wherein:
the base layer is coupled to the second functional layer on a first surface, and is coupled to the first functional layer on a second surface, the first surface and the second surface being on opposite sides of the base layer.

2. The package of claim 1, further comprising an adhesive layer between the first semiconductor device and the second semiconductor device, wherein:
a first surface of the adhesive layer is in contact with the base layer; and
a second surface of the adhesive layer is in contact with the first functional layer, the first surface and the second surface of the adhesive layer being on opposite sides of the adhesive layer.

3. The package of claim 2, further comprising a molding layer over the first functional layer, and encapsulating the second semiconductor device and the adhesive layer, wherein:
the second functional layer is in contact with the molding layer on a first surface and in contact with the base layer on a second surface, the first surface and the second surface of the second functional layer being on opposite sides of the second functional layer.

4. The package of claim 3, further comprising:
a routing layer over the molding layer, the routing layer comprising a conductive routing component encapsulated in an insulating layer;
a first conductive via aside from the second semiconductor device and extending in the molding layer; and
a second conductive via over the second functional layer and extending in the molding layer.

5. The package of claim 4, wherein:
the first conductive via is conductively coupled to the conductive routing component and the first functional layer;
the second conductive via is conductively coupled to the conductive routing component and the second functional layer; and
the second functional component is conductively connected to the first functional component through the first conductive via, the second conductive via, and the conductive routing component.

6. The package of claim 4, further comprising another second conductive via over the second functional layer and extending in the molding layer, the other second conductive via located away from the second conductive layer by a pitch distance,
wherein a ratio between the pitch distance and a vertical dimension of the second conductive via is about 2:1.

7. The package of claim 1, wherein the base layer comprises at least one of a silicon base layer or a molding base layer.

8. The package of claim 1, wherein the first semiconductor device comprises another base layer, the first functional layer being over the other base layer, and
wherein the other base layer comprises at least one of a silicon base layer or a molding base layer.

9. The package of claim 1, wherein the first semiconductor device comprises another base layer, the first functional layer being over the other base layer, and
wherein the base layer and the other base layer each comprises a molding base layer.

10. The package of claim 1, wherein:
the first functional component comprises a controller component and the second functional component comprises a MEMS component;
the first functional component comprises a bulk acoustic wave (BAW) component and the second functional component comprises a low noise amplifier (LNA) component;
the first functional component comprises a power amplifier component and the second functional component comprises a power management chip component; or
the first functional component comprises a MEMS component and the second functional component comprises a controller component.

11. A method for forming a package, comprising:
forming a first structure comprising an adhesive layer and a first functional layer having a first functional component, the first functional layer being over a base layer;
forming a second structure comprising a second functional layer having a second functional component; and
attaching the first structure to the second structure through the adhesive layer such that the first functional layer and the second functional layer are on opposite sides of the base layer.

12. The method of claim 11, wherein the forming of the second structure comprises forming a first conductive via structure in contact with the second functional layer.

13. The method of claim 12, wherein the forming of the first structure comprises:
forming the adhesive layer on the base layer, the adhesive layer and the first functional layer being on opposite sides of the base layer; and
forming a second conductive via structure in contact with the first functional layer.

14. The method of claim 13, further comprising:
forming a molding material layer over the second structure, the molding material layer encapsulating the first structure and the first conductive via structure; and
planarizing the molding material layer, the first conductive via structure, and the second conductive via structure to form a molding layer, a first conductive via, and a second conductive via, wherein the molding layer, the first conductive via, and the second conductive via are coplanar with one another on a respective surface away from the second functional layer.

15. The method of claim 14, further comprising:
forming a routing layer over the molding layer, the first conductive via, and the second conductive via, the routing layer comprising a conductive routing component conductively coupled to the first conductive via and the second conductive via; and
forming a soldering feature conductively coupled to at least one of the first conductive via, the second conductive via, or the conductive routing component.

16. The method of claim 12, wherein the base layer comprises a non-molding material, and the forming of the first structure comprises:
replacing the base layer with a molding base layer;
forming the adhesive layer disposed on the molding base layer, the adhesive layer and the first functional layer being on opposite sides of the molding base layer;
forming a second conductive via structure in contact with the first functional layer; and
forming a first molding material layer over the first functional layer, the first molding material layer encapsulating the second conductive via structure.

17. The method of claim 16, wherein the forming of the first structure comprises, before the replacing of the base layer with the molding base layer:
forming a plurality of second conductive via structures on a first device material layer, the first device material layer being disposed on a first surface of a base material layer;
forming a layer of mold material over the first device material layer such that the layer of mold material encapsulates the plurality of second conductive via structures;
thinning a second surface of the base material layer, the first and second surfaces of the base material layer being on opposite sides of the base material layer; and
dicing the layer of mold material and the thinned base material layer to form the first structure.

18. The method of claim 16, further comprising:
forming a second molding material layer over the second functional layer, the second molding material layer encapsulating the first structure and the first conductive via structure; and
planarizing the first and second molding material layers, the first conductive via structure, and the second conductive via structure to form a molding layer, a first conductive via, and a second conductive via, wherein the molding layer, the first conductive via, and the second conductive via are coplanar with one another on a respective surface away from the second functional layer.

19. The method of claim 18, further comprising:
forming a routing layer over the molding layer, the first conductive via, and the second conductive via, the routing layer comprising a conductive routing component conductively coupled to the first conductive via and or second conductive via; and
forming a soldering feature conductively coupled to at least one of the first conductive via, the second conductive via, or the conductive routing component.

20. The method of claim 11, wherein forming the controller structure comprises:
forming the second functional layer over a non-molding base layer; and
replacing the non-molding base layer with a second molding base layer.
